(19) United States
(12) Patent Application Publication
(10) Pub. No.: US 2016/0128179 A1
(43) Pub. Date: May 5, 2016

(54) ELECTRONIC APPARATUS AND MANUFACTURING METHOD THEREFOR

(71) Applicant: Renesas Electronics Corporation, Tokyo (JP)

(72) Inventors: Manabu Okamoto, Tokyo (JP); Hiroki Shibuya, Tokyo (JP)

(21) Appl. No.: 14/878,107

(22) Filed: Oct. 8, 2015

(30) Foreign Application Priority Data
Oct. 30, 2014 (JP) 2014-221584

(51) Int. Cl. H05K 1/02; H05K 1/18; H05K 3/46; H05K 3/40; H05K 3/30; H05K 1/11; H05K 1/14

(52) U.S. Cl. CPC H05K 1/0268; H05K 1/116; H05K 1/181; H05K 1/145; H05K 3/4038; H05K 3/303; H05K 3/4611; H05K 2201/10886

(57) ABSTRACT

Miniaturization of an electronic apparatus which functions as a component of a wireless communication system is achieved. A main feature point in an embodiment resides in that a plurality of test terminals provided over an upper surface of a wiring board are collectively arranged as shown in a drawing, for example. Thus, it is possible to reduce the size of a test terminal forming area (first test terminal forming area) formed with the test terminals used in a unit test. As a result, miniaturization of an electronic apparatus according to the present embodiment can be achieved.

### CROSS-REFERENCE TO RELATED APPLICATIONS

The disclosure of Japanese Patent Application No. 2014-221584 filed on Oct. 30, 2014 including the specification, drawings and abstract is incorporated herein by reference in its entirety.

### BACKGROUND

The present invention relates to an electronic apparatus and a manufacturing technology therefor, and, for example, a technology effective when applied to an electronic apparatus which functions as a component of a wireless communication system, and a manufacturing technology therefor.

There has been described in Japanese Unexamined Patent Publication Laid-Open No. 2007-313594 (Patent Document 1), a structure in which a sensor control layer and an RF layer are respectively arranged in such a manner that a forming surface of a sensor control unit and an RF unit takes on the side which comes into contact with an MEMS layer, and interpose the MEMS layer therebetween.

There has been described in Japanese Patent Publication No. 2006-505973 (Patent Document 2), a technology in which an antenna area is arranged over a substrate and an RF terminal is included in a die.

There has been described in International Patent Publication No. 2010/026990 (Patent Document 3), a technology in which a transmission circuit package and a reception circuit package are mounted over an antenna substrate as high-frequency circuit packages.

There has been described in Japanese Unexamined Patent Publication Laid-Open No. 2005-207797 (Patent Document 4), a technology having an RF interface block which converts a signal-processed sensing signal to a high frequency signal.

### RELATED ART DOCUMENTS

### Patent Document

[Patent Document 1] Japanese Unexamined Patent Publication Laid-Open No. 2007-313594
[Patent Document 2] Japanese Patent Publication No. 2006-505973
[Patent Document 3] International Patent Publication No. 2010/026990
[Patent Document 4] Japanese Unexamined Patent Publication Laid-Open No. 2005-207797

### SUMMARY

There has been a demand for miniaturization of an electronic apparatus which functions as each node of a wireless communication system, for example. In particular, the current electronic apparatus which configures each node of a wireless sensor network (may be called WSN) corresponding to a kind of wireless communication system using a sensor is of a size of such a level that it offers no difficulty for a person carrying it on. Further, the electronic apparatus has been desired to be minimized to such a level that the person “is not conscious of it” while carrying the same on.

Here, in order to achieve miniaturization of the electronic apparatus, it is important to devise a form of mounting electronic components over a substrate. In the manufacture of the electronic apparatus, however, a test process for selecting a non-defective product and a defective product exists, and the substrate is normally provided with test terminals in order to carryout the test process. Accordingly, it is also important to devise even the form of an arrangement of the test terminals upon achieving the miniaturization of the electronic apparatus. That is, it can be said that it is desirable to devise not only the mounting form of the electronic components but also the arrangement form of the test terminals in an actual electronic apparatus in terms of achievement in its further miniaturization.

Other problems and novel features will be apparent from the description of the present specification and the accompanying drawings.

An electronic apparatus according to one aspect of the present invention includes a module unit in which a first wiring board and a second wiring board are laminated. A plurality of first test terminals are collectively provided in a first test terminal forming area of an upper surface of the first wiring board.

Further, a method for manufacturing an electronic apparatus, according to one aspect of the present invention includes the steps of performing a unit test on a first wiring board by using a plurality of first test terminals formed in an upper surface of a fist wiring board, and performing a coupling test on a module unit by using a plurality of second test terminals formed in a lower surface of the first wiring board.

According to the above one aspect, it is possible to achieve miniaturization of an electronic apparatus.

### BRIEF DESCRIPTION OF THE DRAWINGS

FIG. 1 is a typical diagram showing a general configuration example of an application using a wireless sensor network;

FIG. 2 is a block diagram showing a configuration of a node;

FIG. 3 is a block diagram principally showing a detailed configuration example of a data processing unit included in the node;

FIG. 4 is a block diagram principally showing a detailed configuration example of a transmission part of a radio communication unit included in the node;

FIG. 5 is a block diagram showing a detailed configuration example of a reception part of the radio communication unit included in the node;

FIG. 6 is a perspective view showing an external appearance configuration of an electronic apparatus according to an embodiment;

FIG. 7 is a diagram showing a correspondence relation between a functional configuration of the electronic apparatus according to the embodiment and mounting components of the electronic apparatus;

FIG. 8 is a perspective view typically showing a mounting structure of a wiring board mounted with electronic components;

FIG. 9 is a perspective view typically showing a mounting structure of a wiring board mounted with electronic components;

FIG. 10A is a perspective view showing a mounting structure of a module unit in the embodiment, and FIG. 10B is a side diagram showing the mounting structure of the module unit in the embodiment;

FIG. 11 is a typical transparent top view showing a mounting structure of the electronic apparatus according to the embodiment;

FIG. 12 is a typical transparent side view showing the mounting structure of the electronic apparatus according to the embodiment;

FIG. 13 is a flowchart showing the flow of a manufacturing process of the electronic apparatus, including a test process in the embodiment;

FIG. 14 is a plan diagram showing a layout configuration of an upper surface of the wiring board in the embodiment;

FIG. 15 is a plan diagram showing a layout configuration of a lower surface of the wiring board in the embodiment;

FIG. 16 is a sectional diagram cut along line A-A of FIG. 14;

FIG. 17 is a coupling diagram showing one example of a coupling relationship between terminals used in the test process in the embodiment;

FIG. 18A is a diagram showing a configuration example of coupling two through holes, and FIG. 18B is a diagram showing a configuration example in which a through hole is taken as a long hole having a large size; and

FIG. 19 is a plan view showing the upper surface of the wiring board in the embodiment.

### DETAILED DESCRIPTION

The invention will be described by being divided into a plurality of sections or embodiments whenever circumstances require it for convenience in the following embodiments. However, unless otherwise specified in particular, they are not irrelevant to one another. One thereof has to do with modifications, details, supplementary explanations, etc. of some or all of the other.

Also, when reference is made to the number of elements or the like (including the number of pieces, numerical values, quantity, range, etc.) in the following embodiments, the number thereof is not limited to a specific number and may be greater than or less than or equal to the specific number unless otherwise specified in particular and definitely limited to the specific number in principle.

It is further needless to say that in the following embodiments, components (also including element or factor steps, etc.) employed therein are not always essential unless otherwise specified in particular and considered to be definitely essential in principle.

Similarly, when reference is made to the shapes, positional relations and the like of the components or the like in the following embodiments, they will include ones substantially analogous or similar to their shapes or the like unless otherwise specified in particular and considered not to be definitely so in principle, etc. This is similarly applied even to the above-described numerical values and range.

The same reference numerals are respectively attached to the same members in principle in all the drawings for describing the embodiments, and a repeated description thereof will be omitted. Incidentally, even plan diagrams may be hatched to make the drawings easier to understand.

### Embodiment

<Wireless Sensor Network>

In an embodiment to be described below, a description will be given by taking a wireless sensor network as an example of a wireless communication system. A technical idea in the embodiment is however not limited to this, but can be widely applied to a wireless communication system using a sensor.

The wireless sensor network that is one example of the wireless communication system using the sensor is a technique which has been so attracting attention in recent years. This technique has been expected to be widely used. Each of nodes (terminals) which configure the wireless sensor network is configured to acquire data outputted from a sensor, such as temperatures, illuminance, acceleration, etc. and transmit the acquired data by radio waves. For example, a “multihop ad hoc communication”, which transfers data acquired by nodes using a bucket relay method between the nodes is utilized in the wireless sensor network.

That is, a related art type mobile communication needs the development of infrastructures such as base stations, and a fixed network for coupling these stations, etc. On the other hand, the wireless sensor network using the “multihop ad hoc communication” is capable of communication by autonomous routing of each node itself. Therefore, there is an advantage that the fixed network is not needed for the wireless sensor network and a network can be immediately constructed by simply arranging nodes in the environment desired to construct the network. Incidentally, the type of the wireless sensor network is not limited to it, but maybe a one-to-one type, a star type, a mesh type, or any of them.

Thus, since the autonomous network can be constructed by simply arranging the nodes, the wireless sensor network can obtain an advantage in that laying work at a use site can be reduced. Further, since it is possible to grasp the dynamics of a real world by acquiring data outputted from the sensor, tracking of an object and monitoring of the natural environment have been expected as promising applications for the wireless sensor network.

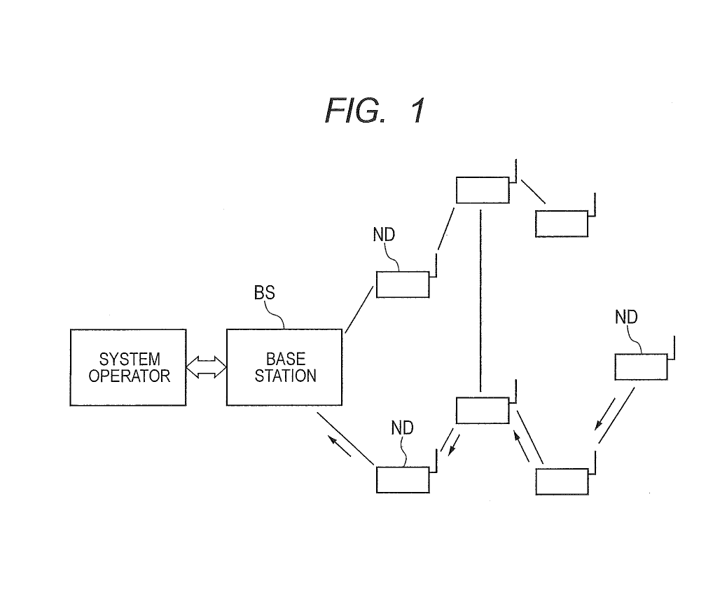

FIG. 1 is a typical diagram showing a general configuration example of an application using a wireless sensor network. In FIG. 1, a plurality of nodes ND are arranged in the wireless sensor network. Each of the nodes ND is configured to observe a surrounding environment using a sensor function. Further, environment data observed by the nodes ND are collected in a base station BS by, for example, the “multihop ad hoc communication” between the nodes ND.

The base station BS is a computer capable of accessing the wireless sensor network. For example, the base station BS collectively holds the environment data obtained from the wireless sensor network. Here, a computer of a system operator desired to acquire environment data from the wireless sensor network accesses, for example, the base station BS to obtain necessary data and analyzes the obtained data. Thus, the computer is capable of grasping the state of areal environment and carrying out processing required by an application, based on the analyzed state.

<Configuration of Node>

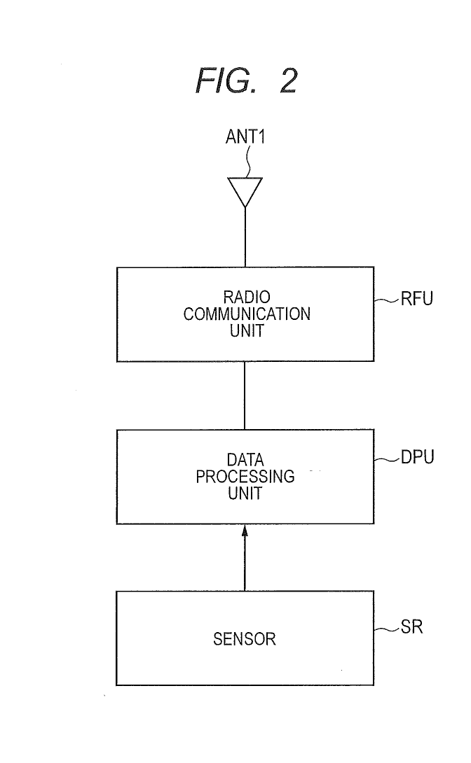

Subsequently, each node which configures the wireless sensor network will be described. FIG. 2 is a block diagram showing the configuration of the node. As shown in FIG. 2, the node which is a component of the wireless sensor network, is equipped with, for example, a sensor SR, a data processing unit DPU, a radio communication unit RFU, and an antenna (communication antenna) ANT1.

The sensor SR is comprised of an element or a device which detects physical quantities such as temperatures, pressure, a flow rate, light, magnetism, etc. and the amounts of changes in those physical quantities. Further, the sensor SR is configured to convert each of the detected amounts of changes into a suitable signal and output the same. The sensor SR includes, for example, a temperature sensor, a pressure sensor, a flow rate sensor, an optical sensor, a magnetic sensor, an illuminance sensor, an acceleration sensor, an angular velocity sensor, or an image sensor or the like.

The data processing unit DPU is configured to process the output signal outputted from the sensor SR and output data of the processed output signal. Further, the radio communication unit RFU is configured to convert the data processed by the data processing unit DPU into a signal of a radio frequency and transmit the same from the antenna ANT1. Furthermore, the radio communication unit RFU is also configured to receive a signal of a radio frequency via the antenna ANT1.

When the physical quantity is detected by the sensor SR at the node configured in this way, a signal is outputted from the sensor SR and the so-outputted signal is inputted to the data processing unit DPU. Then, the data processing unit DPU processes the input signal and outputs data of the processed signal to the radio communication unit RFU. Thereafter, the radio communication unit RFU converts the input data into a signal of a radio frequency and transmits the radio frequency signal from the antenna ANT1. Thus, at the node, the radio frequency signal corresponding to the physical quantity is transmitted based on the physical quantity detected by the sensor SR.

<Detailed Configuration of Node>

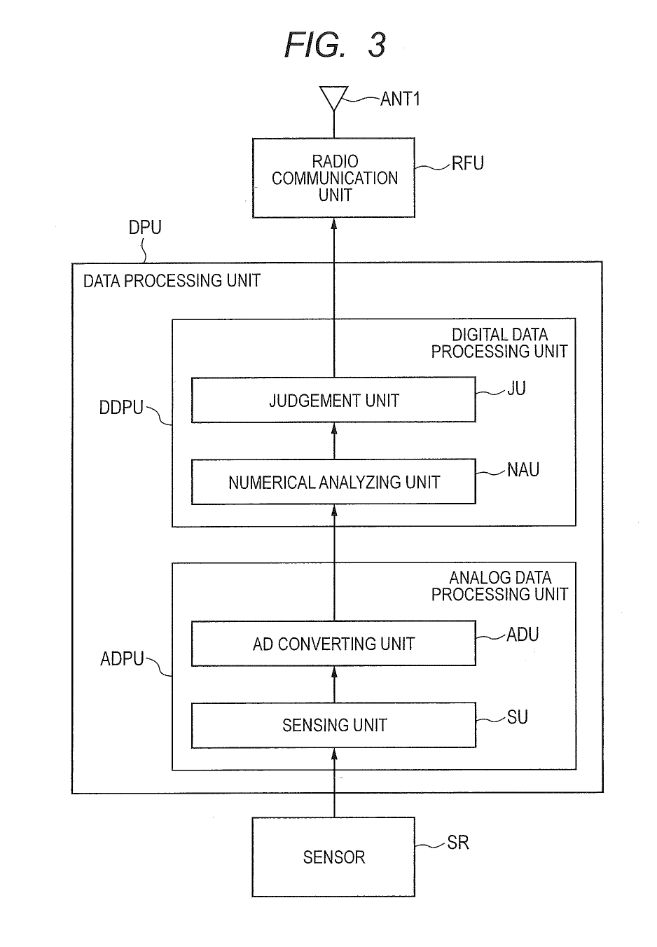

One example of a detailed configuration of the node will further be described. FIG. 3 is a block diagram principally showing a detailed configuration example of the data processing unit DPU included in the node. As shown in FIG. 3, the data processing unit DPU included in the node is comprised of an analog data processing unit ADPU and a digital data processing unit DDPU. Then, the analog data processing unit ADPU is configured to include a sensing unit SU and an AD converting unit ADU. The digital data processing unit DDPU is configured to include a numerical analyzing unit NAU and a judgement unit JU.

Incidentally, the sensor SR may also include one that outputs a digital signal. In this case, the analog data processing unit ADPU becomes unnecessary as the data processing unit DPU. The data processing unit DPU can also be comprised of the digital data processing unit DDPU. In this case, the analog data processing unit ADPU is built in the sensor SR. However, although a description will be made here about a form that the data processing unit DPU is comprised of the analog data processing unit ADPU and the digital data processing unit DDPU as an example, it is not limited to this.

The analog data processing unit ADPU will first be described. The analog data processing unit ADPU is configured to input an analog signal outputted from the sensor SR and covert the analog signal into data easy to handle the analog signal and includes the sensing unit SU and the AD converting unit ADU.

The sensing unit SU is configured to include, for example, an amplifier circuit, a transimpedance circuit, a filter circuit, etc. The output signal outputted from the sensor SR is small and the signal format thereof is not often suitable for processing of the digital data processing unit DDPU. Therefore, there is a need to provide a circuit which amplifies the small analog signal outputted from the sensor SR to an analog signal having a magnitude suitable for the input of the digital data processing unit DDPU. Further, the output signal outputted from the sensor SR may be a current other than the voltage. In this case, an AD converting circuit for converting an analog signal to a digital signal is capable of receiving only a voltage signal. For this reason, there is a need to provide a circuit which amplifies a current signal to a voltage signal having a suitable magnitude while doing conversion to the voltage signal. This circuit is an analog circuit which is called the transimpedance circuit and share the converting circuit and the amplifier circuit. Further, an unnecessary frequency signal (noise) may be mixed into the output signal from the sensor SR. In this case, it becomes hard to obtain the output signal from the sensor SR due to the noise. Therefore, when the noise is a frequency higher than that of the output signal, it is necessary to eliminate the noise by a low-pass filter circuit. On the other hand, when the noise is a frequency lower than that of the output signal, it is necessary to eliminate the noise by a high-pass filter circuit.

Thus, since it is difficult to directly handle the output signal from the sensor SR, the analog data processing unit ADPU is provided, and the sensing unit SU including the above-described amplifier circuit, transimpedance circuit and filter circuit is provided in this analog data processing unit ADPU. The series analog circuits which configure the sensing unit SU are also called an “analog front end (AFE)”.

Next, the AD converting unit ADU is configured to convert analog data outputted from the sensing unit SU into digital data. That is, this is because, since the digital data processing unit DDPU can handle only the digital data, the AD converting unit ADU needs to convert the analog data into the digital data.

Subsequently, the digital data processing unit DDPU is configured to input the digital data outputted from the analog data processing unit ADPU and process the digital data. The digital data processing unit DDPU includes, for example, the numerical analyzing unit NAU and the judgement unit JU. At this time, the digital data processing unit DDPU is comprised of, for example, a micro control unit (MCU).

The numerical analyzing unit NAU is configured to input the digital data outputted from the analog data processing unit ADPU and perform numerical arithmetic processing on the digital data, based on a program. Then, the judgement unit JU is configured to select data to be outputted to the radio communication unit RFU, for example, based on the result of the numerical arithmetic processing by the numerical analyzing unit NAU.

The data processing unit DPU is configured as described above and the following operations thereof will be described. First, the physical quantity such as the temperature, pressure, flow rate, light, magnetism or the like is detected by the sensor SR. A weak detection signal corresponding to an analog signal is outputted from the sensor SR, based on the result of detection. Then, the outputted weak detection signal is inputted to the sensing unit SU in the analog data processing unit ADPU. In the sensing unit SU, the input detection signal is amplified by the amplifier circuit. Also, when the detection signal is not the voltage signal but the current signal, the current signal is converted to the voltage signal by the transimpedance circuit. Further, in order to eliminate noise included in the detection signal, the noise included therein is removed by the filter circuit. Thus, the sensing unit SU processes the detection signal (analog signal) inputted from the sensor SR to generate and output analog data (analog signal). Subsequently, the AD converting unit ADU inputs the analog data outputted from the sensing unit SU therein and converts the same into digital data. Thereafter, the digital data converted by the AD converting unit ADU is inputted to the numerical analyzing unit NAU in the digital data processing unit DDPU. Then, the numerical analyzing unit NAU performs numerical arithmetic processing, based on the input digital data. Thereafter, the judgement unit JU selects digital data to be outputted to the radio communication unit RFU, based on the result of the numerical arithmetic processing. Next, the digital data outputted from the digital data processing unit DDPU is inputted to the radio communication unit RFU where it is converted into a signal of a radio frequency, followed by being transmitted from the antenna ANT1. As described above, the data based on the physical quantity detected by the sensor SR is generated at the node, and the radio frequency signal corresponding to the data is transmitted.

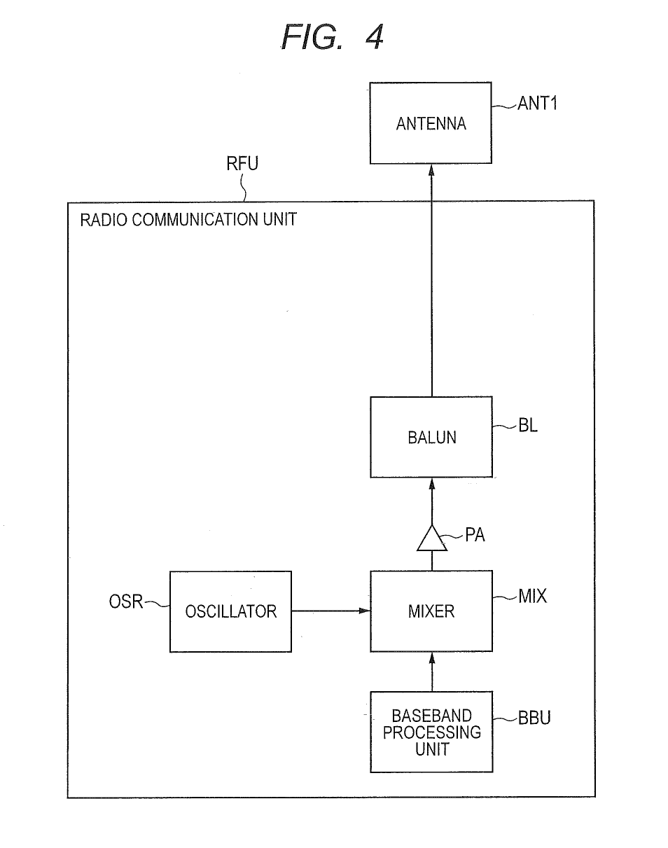

A detailed configuration example of the radio communication unit RFU included in the node will next be described. FIG. 4 is a block diagram principally showing a detailed configuration example of a transmission part of the radio communication unit RFU included in the node. In FIG. 4, the radio communication unit RFU has a baseband processing unit BBU, a mixer MIX, an oscillator OSR, a power amplifier PA, and a balun BL.

The baseband processing unit BBU is configured to generate a modulating baseband signal from the digital data inputted from the data processing unit and process the same. The oscillator OSR is configured to generate a carrier wave of a radio frequency. Further, the mixer MIX is configured to superimpose the baseband signal generated by the baseband processing unit BBU on the carrier wave generated by the oscillator OSR to thereby generate a signal of a radio frequency. Furthermore, the power amplifier PA is configured to amplify the signal of the radio frequency outputted from the mixer MIX, and the balun BL is an element for converting electric signals in balanced and unbalanced states.

The transmission part of the radio communication unit RFU is configured as described above. The operation thereof will be described below. First, the baseband processing unit BBU generates a modulating baseband signal from the digital data inputted from the data processing unit. Then, the baseband signal and the carrier wave generated by the oscillator OSR are modulated by being mixed by the mixer MIX so that a signal of a radio frequency is generated. The radio frequency signal is amplified by the power amplifier PA, followed by being outputted from the radio communication unit RFU through the balun BL. Thereafter, the radio frequency signal outputted from the radio communication unit RFU is transmitted from the antenna ANT1 electrically coupled to the radio communication unit RFU. The radio frequency signal can be transmitted from the node in the above-described manner.

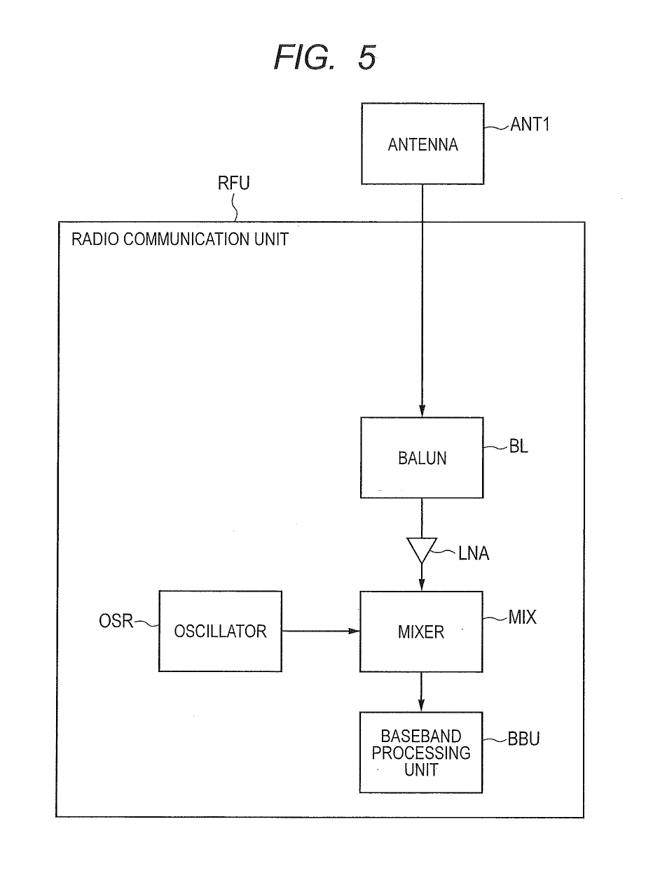

Subsequently, FIG. 5 is a block diagram principally showing a detailed configuration example of a reception part of the radio communication unit RFU included in the node. In FIG. 5, the radio communication unit RFU has a baseband processing unit BBU, a mixer MIX, an oscillator OSR, a low noise amplifier LNA, and a balun BL.

The balun BL is an element for converting electric signals being in balanced and unbalanced states. Further, the low noise amplifier LNA is configured to amplify a received weak reception signal. The oscillator OSR is configured to generate a carrier wave of a radio frequency. The mixer MIX is configured to superimpose the reception signal amplified by the low noise amplifier LNA on the carrier wave generated by the oscillator OSR to thereby generate a baseband signal. The baseband processing unit BBU is configured to generate digital data from the demodulated baseband signal and process the same.

The reception part of the radio communication unit RFU is configured as described above. The operation thereof will be described below. First, a reception signal received by the antenna ANT1 is inputted to the low noise amplifier LNA through the balun BL, where it is amplified. Thereafter, the amplified reception signal is demodulated by being mixed with a carrier wave generated by the oscillator OSR by means of the mixer MIX, so that a baseband signal is generated. Then, the demodulated baseband signal is processed to be converted into digital signal by the baseband processing unit BBU. It is possible to receive the reception signal at the node in the above-described manner.

<External Appearance Configuration of Electronic Apparatus According to the Embodiment>

A description will next be made about an external appearance configuration of an electronic apparatus EA1 according to the present embodiment.

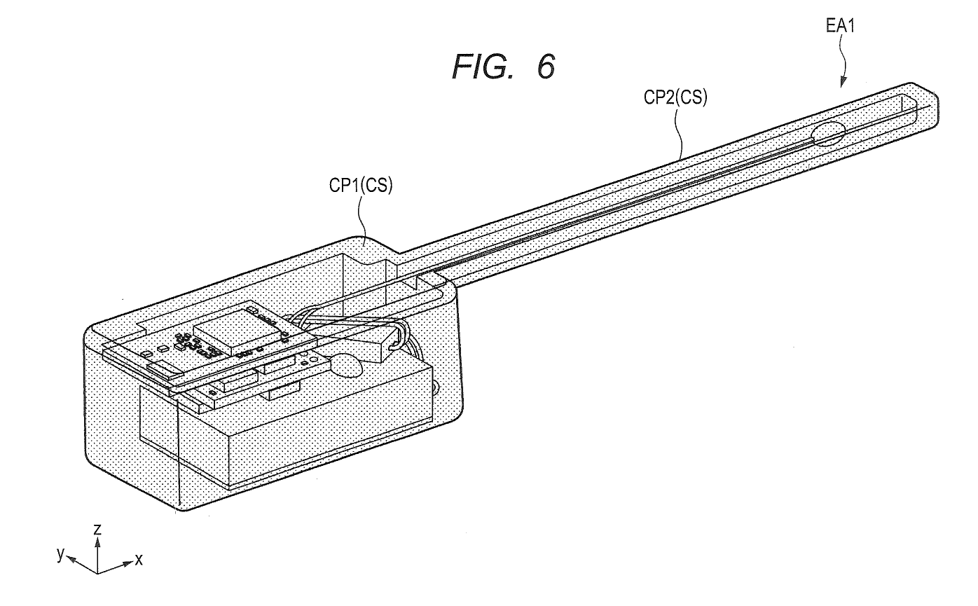

FIG. 6 is a perspective view showing the external appearance configuration of the electronic apparatus EA1 according to the present embodiment. As shown in FIG. 6, the electronic apparatus EA1 according to the present embodiment has a case CS. Components of the electronic apparatus EA1 are accommodated inside the case CS. Incidentally, it is not always required for the electronic apparatus EA1 according to the present embodiment to have the case CS. The components of the electronic apparatus EA1 may not be accommodated in the case CS. A description will however be given here by taking as one example, the electronic apparatus EA1 with the components accommodated in the case CS.

The case CS shown in FIG. 6 is provided with a capacity part CP1 having a first space thereinside, and a capacity part CP2 having a second space thereinside. At this time, the capacity part CP1 and the capacity part CP2 are respectively sealed. That is, the case CS is sealed.

Here, the capacity part CP1 and the capacity part CP2 are coupled integrally to each other and configure the case CS. The capacity part CP1 has a substantially rectangular parallelepiped shape close to a substantially cubic shape as compared with the capacity part CP2. On the other hand, the capacity part CP2 has a substantially rectangular parallelepiped shape more slender than the capacity part CP1. The slender long side of the capacity part CP2 extends in, for example, an x direction.

The case CS in the present embodiment is configured as described above. The components of the electronic apparatus EA1 are accommodated inside the case CS.

<Mounting Structure of Components of Electronic Apparatus>

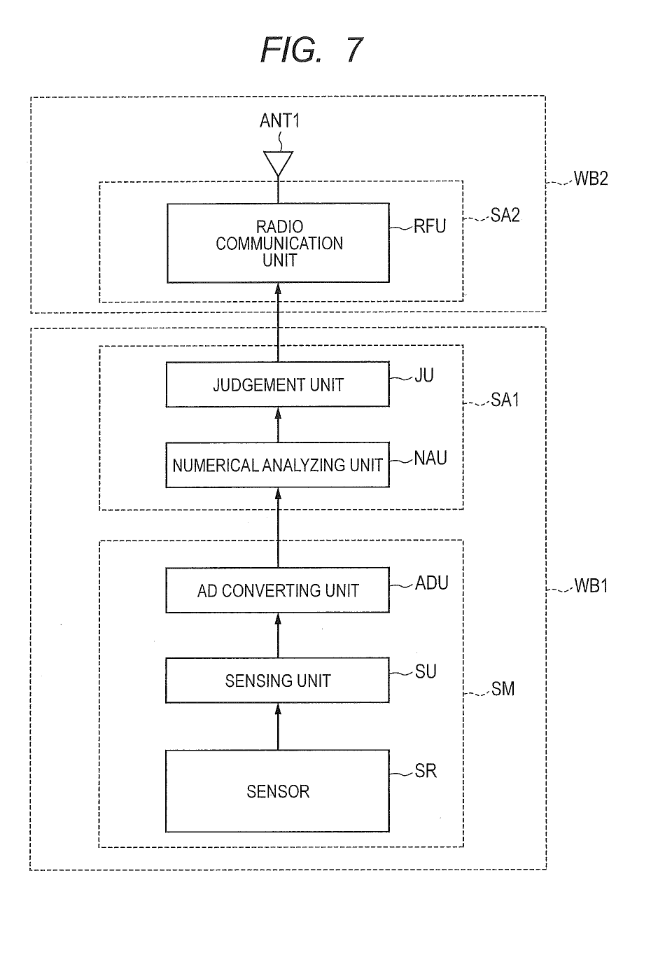

A description will be made below about a mounting structure of the components of the electronic apparatus EA1, which are accommodated inside the case CS. First, FIG. 7 is a diagram showing a correspondence relation between a functional configuration of the electronic apparatus (node) EA1 in the present embodiment and mounting components of the electronic apparatus EA1. In FIG. 7, in the present embodiment, the sensor SR, the sensing unit SU, and the AD converting unit ADU integrally configure a sensor module SM. On the other hand, the numerical analyzing unit NAU and the judgement unit JU are formed in a semiconductor device SA1 which configures an MCU. Then, the sensor module SM and the semiconductor device SA1 are mounted over a common wiring board WB1.

On the other hand, the radio communication unit RFU and the antenna ANT1 are disposed in a wiring board WB2 which is a board different from the wiring board WB1. At this time, of the components of the radio communication unit RFU shown in FIGS. 4 and 5, the baseband processing unit BBU, the oscillator OSR, the mixer MIX, the power amplifier PA, and the low noise amplifier LNA are formed in a semiconductor device SA2 which configures an MCU.

Subsequently, FIG. 8 is a perspective view typically showing a mounting structure of the wiring board WB1 mounted with the electronic components. As shown in FIG. 8, for example, a connector CNT1 and a semiconductor device SA1 are mounted over the surface (upper surface) of the wiring board WB1. This semiconductor device SA1 is formed with the MCU or the like for realizing the numerical analyzing unit NAU and the judgement unit JU shown in FIG. 7. On the other hand, although not illustrated in FIG. 8, for example, the sensor module SM including the sensor SR, the sensing unit SU, and the AD converting unit ADU shown in FIG. 7 is disposed over the back surface (lower surface) of the wiring board WB1. That is, the wiring board WB1 in the present embodiment is mounted with the electronic components at both surfaces of the front and back surfaces.

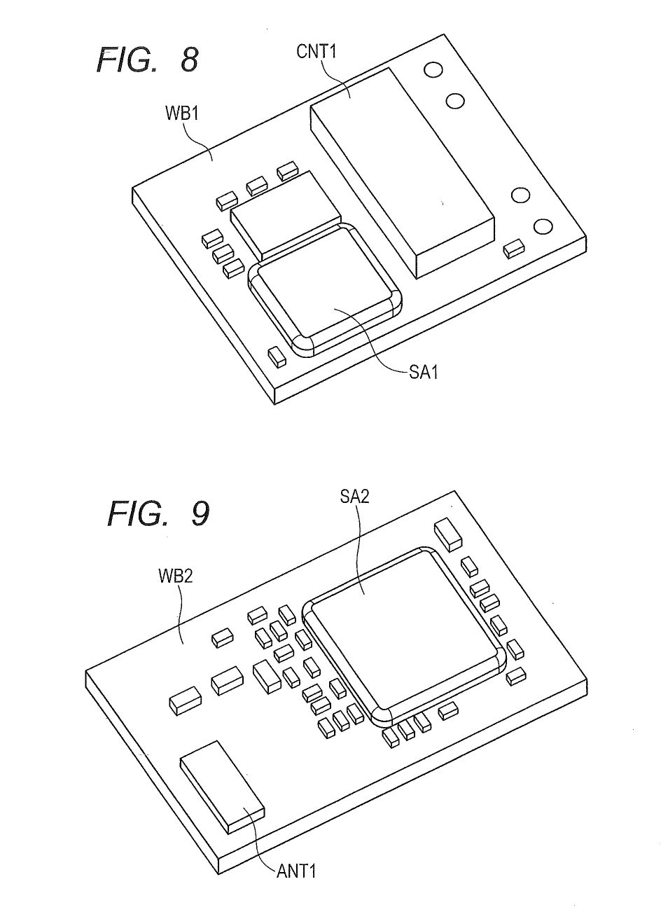

Next, FIG. 9 is a perspective view typically showing a mounting structure of the wiring board WB2 mounted with the electronic components. As shown in FIG. 9, for example, an antenna (antenna part) ANT1 comprised of a chip antenna, and a semiconductor device SA2 are mounted over the surface (upper surface) of the wiring board WB2. Here, the antenna ANT1 can also be comprised of a pattern antenna other than the chip antenna. The semiconductor device SA2 is formed with the main components of the radio communication unit RFU shown in FIG. 7. Thus, the wiring board WB1 is mounted with at least the sensor (sensor module SM) which detects the physical quantity, whereas the wiring board WB2 is mounted with at least the radio communication unit RFU which transmits the data based on the output signal from the sensor. Accordingly, a module unit including the sensor module SM and the radio communication unit RFU has the wiring board WB1 shown in FIG. 8 and the wiring board WB2 shown in FIG. 9. A mounting structure of the module unit will be described below while referring to the drawings.

<Mounting Structure of Module Unit>

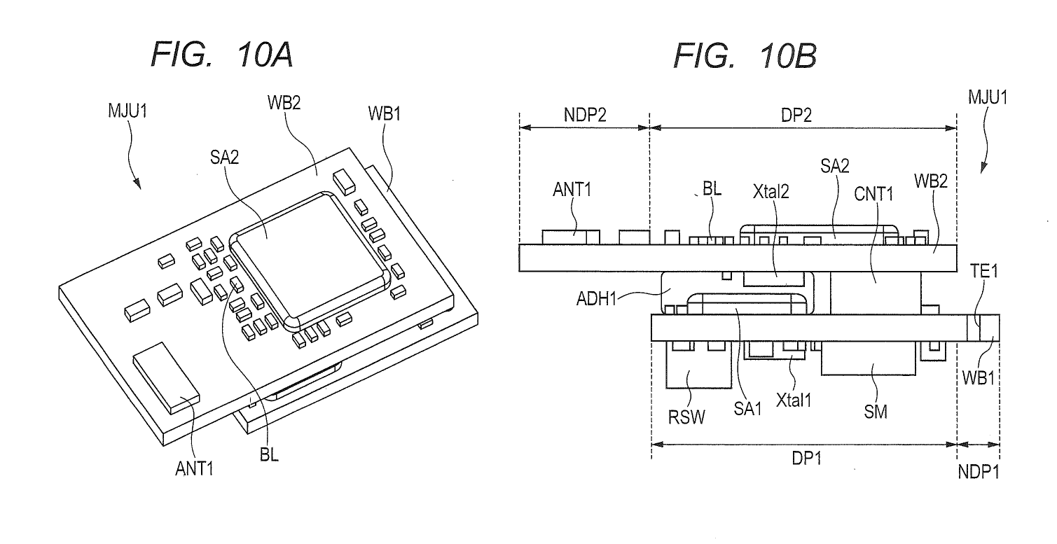

FIG. 10 is a diagram showing the mounting structure of the module unit MJU1 in the present embodiment. Specifically, FIG. 10A is a perspective view showing the mounting structure of the module unit MJU1 in the present embodiment, and FIG. 10B is a side view showing the mounting structure of the module unit MJU1 in the present embodiment.

First, as shown in FIG. 10A, the module unit MJU1 in the present embodiment is comprised of a laminated structure of the wiring board WB1 and the wiring board WB2. For example, the module unit MJU1 in the present embodiment is comprised of the wiring board WB1 arranged at the lower part thereof, and the wiring board WB2 arranged at the upper part of the wiring board WB1.

Thus, according to the module unit MJU1 in the present embodiment, which is comprised of the laminated structure of the wiring board WB1 and the wiring board WB2, for example, the numbers of the electronic components mounted over the wiring board WB1 and the wiring board WB2 respectively are reduced as compared with the case where both of the electronic components mounted over the wiring board WB1 and the electronic components mounted over the wiring board WB2 are mounted over a single wiring board. This means that the plane size of the wiring board WB1 and the plane size of the wiring board WB2 can be reduced. Thus, the entire plane size of the module unit MJU1 comprised of the laminated structure of the wiring board WB1 and the wiring board WB2 small in plane size is greatly made small. As a result, according to the present embodiment, it is possible to achieve miniaturization of the electronic apparatus including the module unit MJU1.

Incidentally, in the present embodiment, the wiring board WB1 and the wiring board WB2 are bonded to each other by not only the connector CNT1 but also an adhesive ADH1 to improve the strength of coupling between the wiring board WB1 and the wiring board WB2. For example, a silicon system adhesive material or the like can be used as the adhesive ADH1, for example.

Then, assumption is made that the module unit MJU1 in the present embodiment is comprised of the laminated structure of the wiring board WB1 and the wiring board WB2. Further, the electronic components are mounted over both surfaces of the wiring board WB1, and the electronic components are mounted even over both surfaces of the wiring board WB2, whereby a further reduction in the plane size of each of the wiring board WB1 and the wiring board WB2 is achieved.

Specifically, as shown in FIG. 10B, in the electronic apparatus provided as the component of the wireless communication system, the present electronic apparatus is provided with the wiring board WB1 and the wiring board WB2 electrically coupled to the wiring board WB1 through the connector CNT1. Further, as shown in FIG. 10B, the wiring board WB1 and the wiring board WB2 are laminated and arranged in a state in which the upper surface of the wiring board WB1 and the lower surface of the wiring board WB2 are made opposite to each other, whereby the module unit MJU1 is configured. At this time, part of the connector CNT1 is mounted over the upper surface of the wiring board WB1. Specifically, the connector CNT1 is configured such that a plug is inserted into a socket (receptacle). For example, the “part of connector CNT1” means either of the socket and the plug. The “other part of the connector CNT1” means the plug where the “part of the connector CNT1” is the socket, and means the socket where the “part of the connector CNT1” is the plug. That is, in the present embodiment, each of the “part of the connector CNT1” and the “other part of the connector CNT1” corresponds to either of the socket and the plug which configure the connector CNT1. Further, the semiconductor device SA1 electrically coupled to the part of the connector CNT1, and the electronic components electrically coupled to the semiconductor device SA1 are mounted over the upper surface of the wiring board WB1. On the other hand, the sensor module SM including the sensor for detecting the physical quantity, and the electronic components such as a reed switch RSW, a crystal oscillator Xtal1, etc. are mounted over the lower surface of the wiring board WB1. The antenna (communication antenna) ANT1, the semiconductor device SA2 electrically coupled to the antenna ANT1, and the electronic components such as the balun BL are mounted over the upper surface of the wiring board WB2, whereas the other part of the connector CNT1 electrically coupled to the semiconductor device SA2, and the electronic components such as a crystal oscillator Xtal2 electrically coupled to the semiconductor device SA2 are mounted over the lower surface of the wiring board WB2.

Thus, according to the present embodiment, since the electronic components are mounted over both surfaces of the wiring board WB1, and the electronic components are mounted even over both surfaces of the wiring board WB2, the plane sizes of the wiring board WB1 and the wiring board WB2 can be reduced. Thus, it is possible to further reduce the entire plane size of the module unit MJU1 comprised of the laminated structure of the wiring board WB1 and the wiring board WB2.

In the so-configured module unit MJU1 in the present embodiment, the radio communication unit RFU and the sensor module SM both included in the module unit MJU1 are separated from each other over the mounting structure. That is, in the present embodiment, the module unit MJU1 is comprised of the wiring board WB1 and the wiring board WB2 different from each other. The sensor module SM is realized by the electronic components (mounting components) mounted over the wiring board WB1, and the radio communication unit RFU is realized by the electronic components (mounting components) mounted over the wiring board WB2.

A description will be made below about an advantage obtained by configuring the radio communication unit RFU and the sensor module SM both included in the module unit MJU1 to be separated from each other over the mounting structure. For example, when the radio communication unit RFU and the sensor module SM integrally configure a module unit over the mounting structure, it is necessary to obtain a radio wave authentication for each module different in sensor, thus resulting in a rise in the manufacturing cost of the module unit.

On the other hand, when the radio communication unit RFU and the sensor module SM are separated from each other over the mounting structure as in the module unit MJU1 in the present embodiment, only the sensor module SM can be customized using in common, the radio communication unit RFU whose radio wave authentication has been acquired. That is, since the wiring board WB2 formed with the radio communication unit RFU can be commonalized, there is no need to acquire the radio wave authentication for each module unit different in the type of sensor even if each sensor module SM differs in configuration, thereby making possible to reduce the manufacturing cost of the entire module unit. The module unit MJU1 corresponding to each sensor different in type can be configured especially by simply commonalizing the mounting structure of the wiring board WB2 formed with the radio communication unit RFU and customizing only the mounting structure of the wiring board WB1 formed with the sensor module SM. Therefore, it is possible to improve the versatility to promote the commonalization of the mounting components for configuring the module unit MJU1. Even from this viewpoint, the manufacturing cost of the module unit MJU1 can be reduced. That is, according to the separation configuration of the module unit MJU1 in the present embodiment, there can be obtained a remarkable advantageous effect that the manufacturing cost of the module unit MJU1 can be greatly reduced by easiness in acquiring the radio wave authentication by communalization of the radio communication unit RFU and an improvement in the versatility due to the communalization of the mounting components.

Subsequently, in the present embodiment, as shown in FIG. 10B, for example, the upper surface of the wiring board WB1 has an overlapping area DP1 overlapped planarly with the wiring board WB2, and a non-overlapping area NDP1 non-overlapped planarly with the wiring board WB2. On the other hand, the upper surface of the wiring board WB2 has an overlapping area DP2 overlapped planarly with the wiring board WB1, and a non-overlapping area NDP2 non-overlapped planarly with the wiring board WB1. At this time, the direction (right direction in FIG. 10) of forming the non-overlapping area NDP1 relative to the overlapping area DP1, and the direction (left direction in FIG. 10) of forming the non-overlapping area NDP2 relative to the overlapping area DP2 are directions opposite to each other.

Further, in the present embodiment, as shown in FIGS. 10A and 10B, the antenna ANT1 is provided in the non-overlapping area NDP2 of the wiring board WB2, whereas other electronic components are provided in an area other than the non-overlapping area NDP2. Here, the effect that “other electronic components are provided in the area other than the non-overlapping area NDP2” is as shown below. Basically, for example, such a configuration that the electronic components (balun BL, semiconductor device SA2, and crystal oscillator Xtal2) other than the antenna ANT1 mounted over the wiring board WB2, the electronic components (semiconductor device SA1, read switch RSW, and crystal oscillator Xtal1) mounted over the wiring board WB1, etc. are arranged so as not to overlap with the non-overlapping area NDP2 is assumed to be a desirable configuration. However, described strictly, no limitation is made to the configuration that other electronic components do not protrude to the non-overlapping area NDP2 side. That is, the term “other electronic components are provided in the area other than the non-overlapping area NDP2” mentioned in the present specification does not exclude the case where some of other electronic components are slightly overlaid over the non-overlapping area NDP2. Even in the case where some of other electronic components slightly overlap with the non-overlapping area NDP2 when it is possible to nearly read that the technical idea that other electronic components are provided in the area other than the non-overlapping area NDP2, has been embodied, it is included in the concept that “other electronic components are provided in the area other than the non-overlapping area NDP2” mentioned in the present specification.

Thus, in the present embodiment, conductor patterns (metal patterns) and electronic components are prevented from being arranged around the antenna ANT1 to the utmost. That is, in plan view, the antenna ANT1 is provided in the position not to overlap with the electronic components corresponding to the components of the module unit MJU1 typified by the sensor module SM and the connector CNT1. Thus, according to the present embodiment, the characteristics of the antenna ANT1 can be improved. As a result, it is possible to lengthen a communication distance of the electronic apparatus. That is, when the conductor patterns and the electronic components exist around the antenna ANT1, the characteristics of the antenna ANT1 are significantly deteriorated due to a shielding effect of electromagnetic waves by the conductor patterns or the electronic components. Therefore, in the present embodiment, the conductor patterns and the electronic components are not arranged around the antenna ANT1 to the utmost.

According to the present embodiment from the above, the communication distance of the electronic apparatus (node) can be lengthened because the characteristics of the antenna ANT1 can be improved. This means that the room for selection of a communication path of the wireless sensor network is enlarged. That is, for example, even if a communication path between adjacent nodes becomes an unusable state due to a communication failure, a communication path with the separated node can be ensured by lengthening the communication distance of the node. Therefore, the wireless sensor network hardly affected by the communication failure can be constructed by using the electronic apparatus according to the present embodiment in each node of the wireless sensor network.

<Mounting Structure of Entire Electronic Apparatus Accommodated in Case>

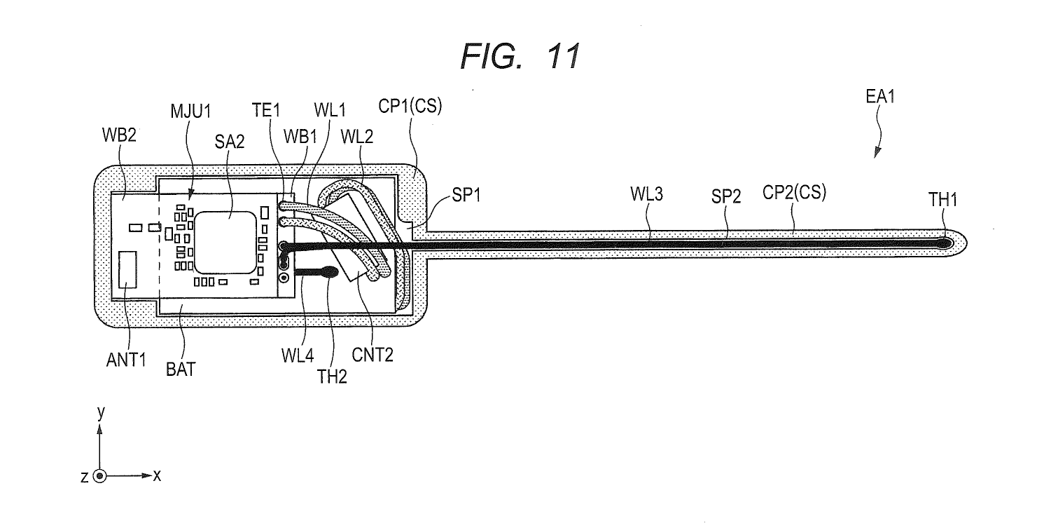

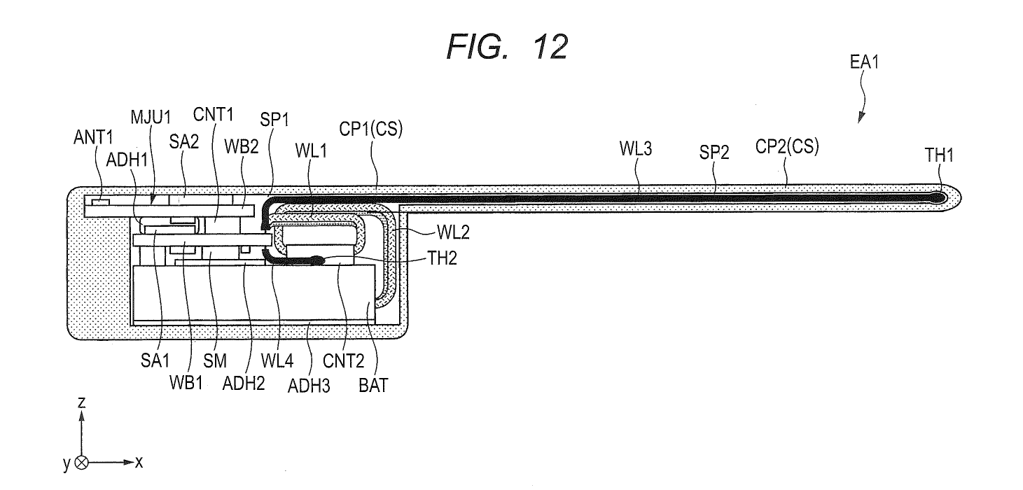

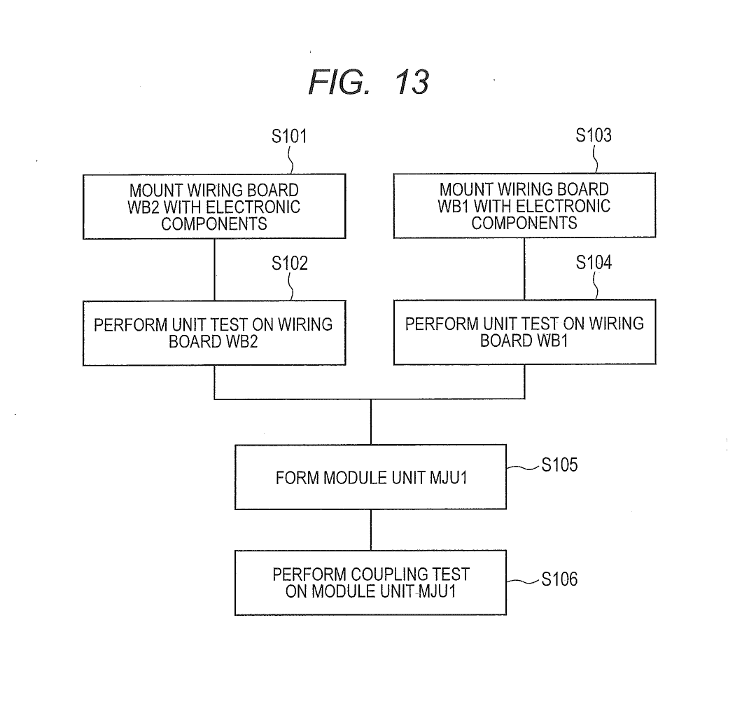

Subsequently, a description will be made about the mounting structure of the entire electronic apparatus EA1 accommodated in the case CS. FIG. 11 is a typical transparent top view showing the mounting structure of the electronic apparatus EA1 according to the present embodiment. Further, FIG. 12 is a typical transparent side view showing the mounting structure of the electronic apparatus EA1 according to the present embodiment.

In FIGS. 11 and 12, the module unit MJU1 comprised of the laminated structure of the wiring board WB1 and the wiring board WB2, a battery BAT, and a coupling part for electrically coupling the module unit MJU1 and the battery BAT are accommodated in the space SP1 inside the capacity part CP1 which configures part of the case CS. For example, in the present embodiment, the battery BAT is disposed over the bottom of the capacity part CP1 as shown in FIG. 12. Then, the wiring board WB1 is disposed above the battery BAT, and the wiring board WB2 is disposed above the wiring board WB1. Further, the coupling part is also disposed over the battery BAT. At this time, the coupling part is comprised of, for example, a wiring WL1 which couples a connector CNT2 and the wiring board WB1 of the module unit MJU1, and a wiring WL2 which couples the connector CNT2 and the battery BAT. Further, a thermistor TH2 which measures the temperature of the battery BAT, and a wiring WL4 electrically coupled to the thermistor TH2 are disposed over the battery BAT. The wiring WL4 is coupled to the wiring board WB1.

Incidentally, as the battery BAT in the present embodiment, a rechargeable secondary battery is used. As one example of the secondary battery, may be mentioned a lithium ion battery. Further, as the rechargeable secondary battery, for example, an electric double-layered capacitor or the like can be used. That is, the “secondary battery” mentioned in the present specification is used in a wide concept that it includes a chargeable/dischargeable storage device. The electric double-layered capacitor is also included in the “secondary battery” mentioned in the present specification.

On the other hand, in the case CS in the present embodiment, the capacity part CP2 is provided to be coupled to the capacity part CP1. A thermistor TH1 which serves as a temperature sensor, and a wiring WL3 electrically coupled to the thermistor TH1 are accommodated in a space SP2 lying inside the capacity part CP2. Further, the space SP1 lying inside the capacity part CP1 and the space SP2 lying inside the capacity part CP2 are in communication with each other. The wiring WL3 coupled to the thermistor TH1 is coupled to the wiring board WB1 of the module unit MJU1. The thermistor TH1 accommodated in the space SP2 lying inside the capacity part CP2 has, for example, the function of measuring the temperature of an external environment under which the electronic apparatus EA1 is installed.

Thus, although the electronic apparatus EA1 according to the present embodiment is equipped with the thermistors TH1 and TH2 as the temperature sensors, this configuration is merely one example. For example, the electronic apparatus EA1 may be equipped with only either of the thermistors TH1 and TH2. Alternatively, the electronic apparatus EA1 may be configured so as not to be equipped with both of them.

The electronic apparatus EA1 according to the present embodiment configured as described above is of the electronic apparats which functions as the component (node) of the wireless communication system. The electronic apparatus EA1 is equipped with the module unit MJU1, the battery BAT which supplies power to the module unit MJU1, and the coupling part which electrically couples the module unit MJU1 and the battery BAT. At this time, the module unit MJU1 has the sensor which detects the physical quantity, and the radio communication unit which transmits data based on the output signal from the sensor.

Subsequently, in the present embodiment, as shown in FIGS. 10 and 11, for example, the non-overlapping area NDP1 of the wiring board WB1 is formed with external terminals TE1 each having a penetration structure, which penetrate the wiring board WB1. A junction part between the wiring board WB1 (module unit MJU1) and the wiring WL1 (wiring WL2) is formed by inserting the wirings WL1 and WL2 in the external terminals TE1 each having the penetration structure and bonding them with solder. Likewise, as shown in FIGS. 11 and 12, not only the wirings WL1 and WL2 but also the wiring WL3 electrically coupled to the thermistor TH1 and the wiring WL4 electrically coupled to the thermistor TH2 are inserted into the external terminals TE1 each having the penetration structure formed in the non-overlapping area NDP1 of the wiring board WB1 to form a junction part.

Thus, according to the present embodiment, it is possible to obtain advantages to be shown below. The junction part which couples the wiring board WB1 and the wiring WL1 (wiring WL2) is formed in the non-overlapping area NDP1 (refer to FIG. 10) of the wiring board WB1, which is farthest away from the non-overlapping area NDP2 (refer to FIG. 10) of the wiring board WB2 with the antenna ANT1 disposed thereover. As a result, according to the present embodiment, the characteristics of the antenna ANT1 are hardly affected by the junction part which couples the wiring board WB1 and the wiring WL1. Thus, it is possible to improve the characteristics of the antenna ATN1 formed in the non-overlapping area NDP2 (refer to FIG. 10).

Further, the junction part is formed by inserting the wiring WL1 (wiring WL2) in the external terminal TE1 having the penetration structure, which is formed in the wiring board WB1 and bonding them with solder. Therefore, the junction strength between the wiring board WB1 and the wiring WL1 can be improved by insertion of the wiring WL1 inside the external terminal TE1 having the penetration structure as compared with, for example, the case where the wiring WL1 is solder-bonded to a pad formed at the surface of the wiring board WB1 to form a junction part. Likewise, according to the present embodiment, it is possible to improve the junction strength between the wiring board WB1 and the wiring WL2, the junction strength between the wiring board WB1 and the wiring WL3, and the junction strength between the wiring board WB1 and the wiring WL4.

Further, as an advantage that the junction part between the module unit MJU1 and the coupling part is formed in the non-overlapping area NDP1 of the wiring board WB1 shown in FIG. 10, there can be mentioned an advantage that soldering of the junction part becomes easy even after the wiring board WB1 and the wiring board WB2 are laminated and arranged (after lamination and assembly thereof).

<Need for Examinations on Test Process>

The electronic apparatus according to the present embodiment is configured as described above. In the manufacturing process of the electronic apparatus, a test process for selecting the quality of the electronic apparatus is carried out. That is, in order to prevent defective products from being shipped, as much as possible, a test process for selecting non-defective and defective products exists in the manufacturing process of the electronic apparatus, and only an electronic apparatus determined to be a non-defective product which has passed the test process is shipped. Thus, the electronic apparatus is normally provided with test terminals used in the test process. Further, in view of a reduction in the cost of the electronic apparatus, it is necessary to suppress the entire electronic apparatus including other non-defective components from being processed as a defective product due to failures in some components. To this end, it becomes important to devise the test process.

When paying attention to the electronic apparatus according to the present embodiment, for example, as shown in FIGS. 10A and 10B, the electronic apparatus according to the present embodiment has the module unit MJU1. This module unit MJU1 is comprised of the laminated structure in which the wiring board WB1 mounted with the electronic components and the wiring board WB2 mounted with the electronic components are coupled to each other by the connector CNT1.

Thus, when the test process is carried out after the assembly of the module unit MJU1, the module unit MJU1 determined to be “NG” in the test process is discarded as a defective product. At this time, for example, in the module unit MJU1 to be discarded, the wiring board WB2 mounted with the electronic components is a defective product, whereas the wiring board WB1 mounted with the electronic components may be a non-defective product. In this case, since the entire module unit MJU1 becomes a defective product regardless of the wiring board WB1 mounted with the electronic components being the non-defective product, the wiring board WB1 (non-defective product) mounted with the electronic components is discarded.

Particularly, since the wiring board WB1 and the wiring board WB2 are not only coupled by the connector CNT1 but also adhered with the adhesive ADH1 in the module unit MJU1 in the present embodiment, it is difficult to take out the non-defective wiring board WB1 mounted with the electronic components from the integrated module unit MJU1. From this point, for example, when the test process is carried out in the module unit MJU1 in the present embodiment after the assembly of the module unit MJU1, the entire module unit MJU1 becomes a defective product regardless of the wiring board WB1 mounted with the electronic components being non-defective. Therefore, the wiring board WB1 as the non-defective product mounted with the electronic components is also discarded. This means that it will result in an increase in the cost of the electronic apparatus.

In the present embodiment from the above, it cannot be said that the execution of the test process including the tests on the individual wiring boards WB1 and WB2 after the assembly of the module unit MJU1 comprised of the laminated structure of the wiring board WB1 mounted with the electronic components and the wiring board WB2 mounted with the electronic components is appropriate in terms of reducing the cost of the electronic apparatus. That is, upon carrying out the test process on the module unit MJU1 in the present embodiment, it is necessary to devise a test method capable of reducing the cost of the entire electronic apparatus in consideration of the fact that the module unit MJU1 is comprised of the laminated structure of the wiring board WB1 mounted with the electronic components and the wiring board WB2 mounted with the electronic components. Thus, in the present embodiment, the test method is devised considering that the module unit MJU1 is comprised of the laminated structure of the wiring board WB1 mounted with the electronic components and the wiring board WB2 mounted with the electronic components. A description will be made below about a technical idea in the present embodiment to which this devise has been applied.

<Test Process in the Embodiment>

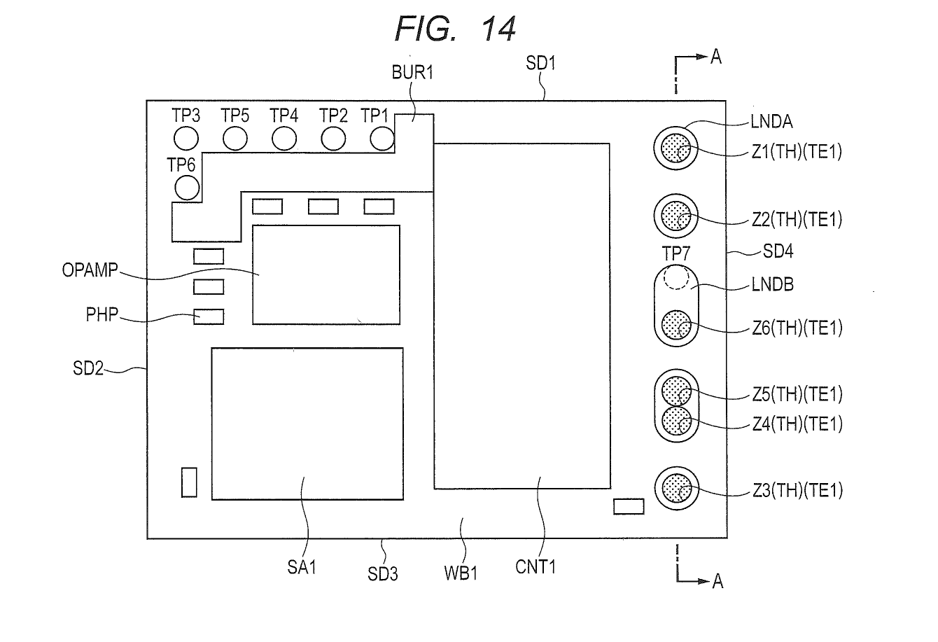

FIG. 13 is a flowchart showing the flow of the manufacturing process of the electronic apparatus, including the test process in the present embodiment. As shown in FIG. 13, in the manufacturing process of the electronic apparatus according to the present embodiment, the wiring board WB2 is first mounted with the electronic components (S101). Thereafter, a unit test is carried out in a state of the wiring board WB2 being mounted with the electronic components (S102). Likewise, the wiring board WB1 is mounted with the electronic components (S103). Thereafter, a unit test is carried out in a state of the wiring board WB1 being mounted with the electronic components (S104). Then, the wiring board WB2 mounted with the electronic components, which has been determined to be a non-defective product in the unit test, and the wiring board WB1 mounted with the electronic components, which has been determined to be a non-defective product in the unit test, are laminated and coupled to form the module unit MJU1 (S105). Thereafter, a coupling test is performed on the module unit MJU1 in which the wiring board WB1 and the wiring board WB2 are laminated and coupled (S106). The manufacturing process of the electronic apparatus including the test process in the present embodiment is realized in the above-described manner. Incidentally, although there is a case where in the present specification, the term “unit test on the wiring board mounted with the electronic components” is expressed as the “unit test on the wiring board” for convenience, the term “unit test on the wiring board” means the unit test on the entire wiring board mounted with the electronic components.

The electronic apparatus according to the present embodiment includes the electronic apparatus which functions as each component of the wireless communication system. The electronic apparatus is equipped with the wiring board WB1 and the wiring board WB2 electrically coupled to the wiring board WB1 through the connector CNT1. At this time, the wiring board WB1 and the wiring board WB2 are laminated and arranged in the opposed state of the upper surface of the wiring board WB1 and the lower surface of the wiring board WB2 to configure the module unit MJU1. Then, a plurality of first test terminals are collectively provided in a first test terminal forming area of the upper surface of the wiring board WB1. Further, a plurality of second test terminals are collectively provided in a second test terminal forming area of the lower surface of the wiring board WB1.

The manufacturing process of the electronic apparatus according to the present embodiment configured in this way has a step of mounting the electronic components over the upper surface of the wiring board WB1 and a step of mounting the electronic components over the lower surface of the wiring board WB1. Likewise, the manufacturing process of the electronic apparatus according to the present embodiment has a step of mounting the electronic components over the upper surface of the wiring board WB2 and a step of mounting the electronic components over the lower surface of the wiring board WB2. Thereafter, the unit test on the wiring board WB1 is carried out by using the first test terminals. Likewise, the unit test on the wiring board WB2 is carried out by using the test terminals provided in the wiring board WB2. Subsequently, the wiring board WB1 having passed the unit test and the wiring board WB2 having passed the unit test are coupled to each other by the connector CNT1 to thereby form the module unit MJU1, and thereafter the coupling test on the module unit MJU1 is carried out by using the second test terminals. Consequently, the manufacturing process of the electronic apparatus including the test process in the present embodiment is realized.

In this regard, for example, in the case of the related art which performs the test process after assembly of the module unit MJU1, the module unit MJU1 determined to be “NG” in this test process is discarded as a defective product. At this time, in the discarded module unit MJU1, while the wiring board WB2 mounted with the electronic components is defective, the wiring board WB1 mounted with the electronic components may be non-defective. In this case, since the entire module unit MJU1 becomes defective regardless of the wiring board WB1 mounted with the electronic components being non-defective, the wiring board WB1 (non-defective product) mounted with the electronic components is also discarded.

On the other hand, according to the present embodiment, before the formation of the module unit MJU1, first, the unit test on the wiring board WB1 mounted with the electronic components is carried out, and the unit test on the wiring board WB2 mounted with the electronic components is carried out. Further, in the present embodiment, the module unit MJU1 is formed using the wiring board WB1 determined to be non-defective in the unit test and the wiring board WB2 determined to be non-defective in the unit test. Therefore, in the present embodiment, it is not considered that either of the wiring board WB1 and the wiring board WB2 configuring the module unit is comprised of the defective product, and the other thereof is comprised of the non-defective product. From this point, according to the present embodiment, the non-defective product configuring part of the module unit MJU1 which is defective can be suppressed from being wasted as in the related art. As a result, according to the manufacturing method of the electronic apparatus in the present embodiment, the manufacturing cost of the electronic apparatus can be reduced.

In the test process in the present embodiment as described above, after execution of the unit test on the wiring board WB1 and the unit test on the wiring board WB2, the module unit MJU1 comprised of the laminated structure of the wiring board WB1 and the wiring board WB2 is formed, and the coupling test on the module unit MJU1 is carried out. In this case, in regard to the unit test on the wiring board WB2, a plurality of test terminals are further provided over the lower surface of the wiring board WB2 with the connector CNT1 disposed thereover, considering that needle application is performed even onto the connector CNT1, whereby the unit test on the wiring board WB2 is executed at the lower surface of the wiring board WB2. On the other hand, in regard to the unit test on the wiring board WB1, a plurality of test terminals are further provided over the upper surface of the wiring board WB1 with the connector CNT1 disposed thereover, considering that the needle application is performed on the connector CNT1, whereby the unit test on the wiring board WB1 is performed at the upper surface of the wiring board WB1. Further, in regard to the coupling test subsequent to the formation of the module unit MJU1, a plurality of test terminals are provided over the lower surface of the wiring board WB1, whereby the coupling test on the module unit MJU1 is performed at the lower surface of the wiring board WB1. This is because, since the module unit MJU1 is formed by lamination in the state in which the upper surface of the wiring board WB1 and the lower surface of the wiring board WB2 are made opposite to each other, the needle application cannot be performed on the upper surface of the wiring board WB1 or the lower surface of the wiring board WB2 after the formation of the module unit MJU1. From this point, the coupling test after the formation of the module unit MJU1 is performed at the lower surface of the wiring board WB1 by using the test terminals provided over the lower surface of the wiring board WB1.

Now, as a configuration that the coupling test on the module unit MJU1 is performed after the formation of the module unit MJU1, there are considered a configuration that test terminals are provided over the upper surface of the wiring board WB2 to execute the coupling test, and a configuration that test terminals are provided over the lower surface of the wiring board WB1 to execute the coupling test. In this regard, in the present embodiment, the configuration that the test terminals are provided over the lower surface of the wiring board WB1 to carry out the coupling test on the module unit MJU1 is adopted. This reason is however as follows: While power is supplied from an external power supply such as a battery to the module unit MJU1, an external terminal supplied with external power from the external power supply is provided over the lower surface of the wiring board WB1, and the coupling test on the module unit MJU1 is required to be done using the external power supplied from the external power supply and GND (ground). From this point, in the present embodiment, the configuration that the test terminals are provided over the lower surface of the wiring board WB1 to execute the coupling test is adopted as the configuration to execute the coupling test on the module unit MJU1.

From the above, in the test process in the present embodiment, the test terminals are provided over the upper surface of the wiring board WB1 to carry out the unit test on the wiring board WB1, and the coupling test after the formation of the module unit MJU1 is carried out using the test terminals provided over the lower surface of the wiring board WB1. From this point, in the present embodiment, the test terminals are provided over both of the upper and lower surfaces of the wiring board WB1. That is, in the present embodiment, the test terminals are provided over both surfaces of the wiring board WB1 to execute the test process that the module unit MJU1 is formed to carry out the coupling test on the module unit MJU1 after the execution of the unit test on each of the wiring boards WB1 and WB2. That is, the test process in the present embodiment is realized by the configuration that the test terminals are provided over both surfaces of the wiring board WB1.

<Layout Configuration of Wiring Board WB1>

A description will next be made about a layout configuration of the wiring board WB1. FIG. 14 is a plan diagram showing the layout configuration of the upper surface of the wiring board WB1 in the present embodiment. In FIG. 14, the wiring board WB1 in the present embodiment is in the form of a rectangular shape comprised of a rectangular parallelepiped shape. The wiring board WB1 has sides SD1 and SD3 opposite to each other and has sides SD2 and SD4 opposite to each other. At this time, the sides SD1 and SD2 intersect each other, and the sides SD1 and SD4 intersect each other. Likewise, the sides SD3 and SD2 intersect each other, and the sides SD3 and SD4 intersect each other. Further, as shown in FIG. 14, a connector CNT1 (which is strictly part of the connector CNT1, but called the connector CNT1 for convenience) is mounted over the upper surface of the wiring board WB1. Here, the connector CNT1 mounted over the wiring board WB1 is disposed close to the side SD4 side. As a result, as shown in FIG. 14, a space is ensured in the left area (side SD2 side) of the connector CNT1 at the upper surface of the wiring board WB1. A semiconductor device SA1, an op amplifier OPAMP, and parts PHP around the op amplifier are disposed in the space. Thus, the above-described electronic components are disposed in the space developed by shifting the position of arrangement of the connector CNT1 to the side SD4 side to thereby effectively utilize the upper surface of the wiring board WB1. As a result, it is possible to achieve miniaturization of the wiring board WB1.

Here, in FIG. 14, the semiconductor device SA1 is a data processing unit which processes a signal outputted from a sensor and outputs the processed signal to a radio communication unit. The semiconductor device SA1 functions as a digital data processing unit of the data processing unit comprised of an analog data processing unit and a digital data processing unit. Further, the semiconductor device SA1 also has a function as an AD converting unit which converts an analog signal into a digital signal. Then, as shown in FIG. 14, the op amplifier OPAMP which outputs a reference potential to the AD converting unit is mounted overt the upper surface of the wiring board WB1 so as to adjoin the semiconductor device SA1. Further, the peripheral parts PHP of the op amplifier OPAMP are mounted around the op amplifier OPAMP. Thus, since the semiconductor device SA1 having the function as the AD converting unit, the op amplifier OPAMP which outputs the reference potential to the AD converting unit, and the peripheral parts are disposed adjacent to each other over the upper surface of the wiring board WB1, it is possible to suppress degradation in the reference potential for which accuracy is required. That is, according to the present embodiment, the plan size of the wiring board WB1 can be miniaturized by effectively utilizing the upper surface of the wiring board WB1, and an improvement in the performance as the electronic apparatus can be achieved by mounting the parts related to each other together as the electronic components disposed over the upper surface of the wiring board WB1.

Further, as shown in FIG. 14, a plurality of test terminals TP1 to TP6 are collectively provided in a test terminal forming area of the upper surface of the wiring board WB1. Particularly when of the upper surface of the wiring board WB1, an area in which the electronic components typified by the semiconductor device SA1, the op amplifier OPAMP, and the peripheral parts PHP are mounted is defined as a part mounting area (first part mounting area) in FIG. 14, a buffer area BUR1 having a prescribed space is provided between the test terminal forming area and the part mounting area in plan view. At this time, as shown in FIG. 14, for example, a visible outline of the test terminal forming area is formed so as to include part of the side SD1 and part of the side SD2. Thus, according to the present embodiment, the test terminals TP1 to TP6 can locally be provided in a collective manner in the test terminal forming area having the minimum required size. The test terminals TP1 to TP6 provided in such a test terminal forming area are unit test terminals relative to the single wiring board WB1 prior to the module unit MJU1 being configured.

Besides, as shown in FIG. 14, the upper surface of the wiring board WB1 has a through hole forming area in which a plurality of through holes (through holes passing therethrough) TH are formed. The through hole forming area is formed on the side SD4 side, and the through holes TH are disposed along the side SD4. At this time, each of the through holes TH configures each of a plurality of external terminals TE1. The external terminals TE1 include an external power supply terminal Z1, a GND terminal Z2, a first external sensor input terminal Z3, a first external sensor GND terminal Z4, a second external sensor GND terminal Z5, and a second external sensor input terminal Z6. Further, the test terminals TP1 to TP6 and the external terminals TE1 (through holes TH) are respectively electrically coupled. Incidentally, in the present embodiment as shown in FIG. 14, a test terminal TP7 is also provided at part of the through hole forming area, but the test terminal TP7 is also a unit test terminal as with the test terminals TP1 to TP6 and is electrically coupled to the external terminal TE1 (through hole TH).

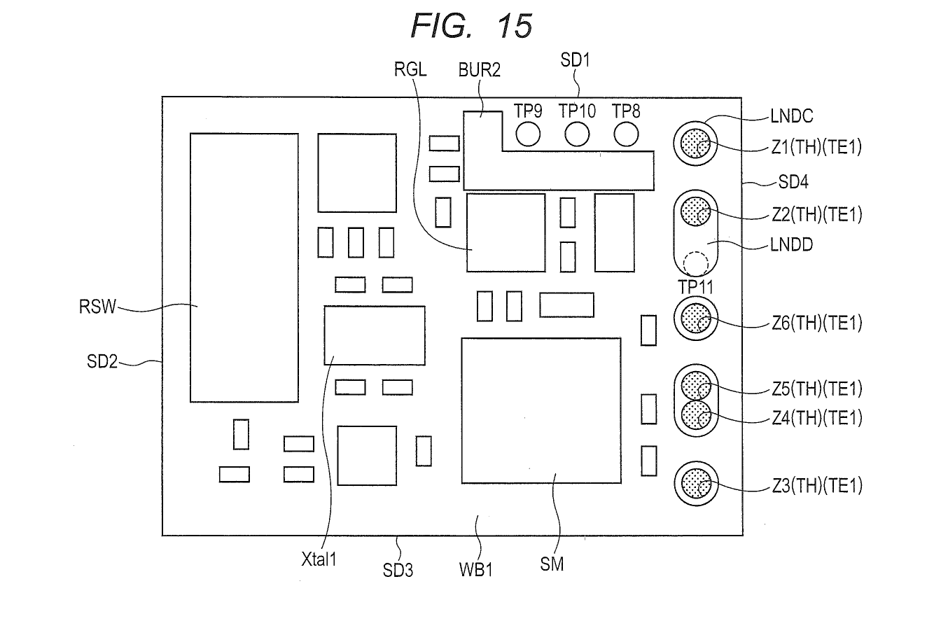

Subsequently, FIG. 15 is a plan diagram showing a layout configuration of the lower surface of the wiring board WB1 in the present embodiment. In FIG. 15, for example, a sensor module SM including an acceleration sensor, a regulator RGL which generates an internal power supply (internal power supply voltage) used inside the module unit MJU1 from the external power supply (external power supply voltage), a crystal oscillator Xtakl1 which outputs a reference clock to the semiconductor device SA1, a reed switch RSW, etc. are mounted over the lower surface of the wiring board WB1. In the present embodiment in particular, as can be seen from FIGS. 14 and 15, the crystal oscillator Xtal1 is disposed in an area in which it overlaps with the semiconductor device SA1 in plan view. Thus, according to the present embodiment, since the semiconductor device SA1 and the crystal oscillator Xtal1 can be arranged close to each other, the reference clock outputted from the crystal oscillator Xtal1 can be inputted to the semiconductor device SA1 without degrading the reference clock.

In the present embodiment, as shown in FIGS. 14 and 15, the sensor module SM is disposed in an area in which it overlaps with the connector CNT1 in plan view. In this case, since the sensor module SM is disposed over the back surface of a part for fixing the connector CNT1 which couples the wiring board WB1 and the wiring board WB2, the sensor module SM is hardly affected by noise due to rattling, and high sensitivity of the sensor module SM can be achieved.

Also, in the present embodiment, as shown in FIG. 15, the reed switch RSW operated by magnetism is mounted over the lower surface of the wiring board WB1. For example, the electronic apparatus according to the present embodiment includes a sealed case to enhance waterproofness and dustproofness. This case is provided with a capacity part having a space and configured such that the module unit MJU1 is accommodated in the space of the capacity part. In this case, with the provision of the reed switch RSW, the reed switch RSW is turned ON/OFF by external control by magnetism even in a state in which the module unit MJU1 is being accommodated in the case, to enable a power supply to be turned on to the module unit MJU1.

Further, as shown in FIG. 15, a plurality of test terminals TP8 to TP10 are collectively provided in a test terminal forming area of the lower surface of the wiring board WB1. Particularly when of the lower surface of the wiring board WB1, an area in which the electronic components typified by the sensor module SM, the regulator RGL, the crystal oscillator Xtal1, and the reed switch RSW are mounted is defined as a part mounting area (second part mounting area) in FIG. 15, a buffer area BUR2 having a prescribed space is provided between the test terminal forming area and the part mounting area in plan view. At this time, as shown in FIG. 15, for example, a visible outline of the test terminal forming area is formed so as to include part of the side SD1. Thus, according to the present embodiment, the test terminals TP8 to TP10 can locally be provided in a collective manner in the test terminal forming area having the minimum required size. The test terminals TP8 to TP10 provided in such a test terminal forming area are coupling test terminals used for the coupling test with the wiring board WB1 and the wiring board WB2 after the configuration of the module unit MJU1.

Besides, as shown in FIG. 15, the lower surface of the wiring board WB1 has a through hole forming area in which a plurality of through holes (through holes passing therethrough) TH are formed. The through hole forming area is formed on the side SD4 side, and the through holes TH are disposed along the side SD4. At this time, each of the through holes TH configures each of a plurality of external terminals TE1. The external terminals TE1 include an external power supply terminal Z1, a GND terminal Z2, a first external sensor input terminal Z3, a first external sensor GND terminal Z4, a second external sensor GND terminal Z5, and a second external sensor input terminal Z6. Further, the test terminals TP8 to TP10 and the external terminals TE1 (through holes TH) are respectively electrically coupled. Incidentally, in the present embodiment as shown in FIG. 15, a test terminal TP11 is also provided in part of the through hole forming area, but the test terminal TP11 is also a coupling test terminal as with the test terminals TP8 to TP10 and is electrically coupled to the external terminal TE1 (through hole TH).

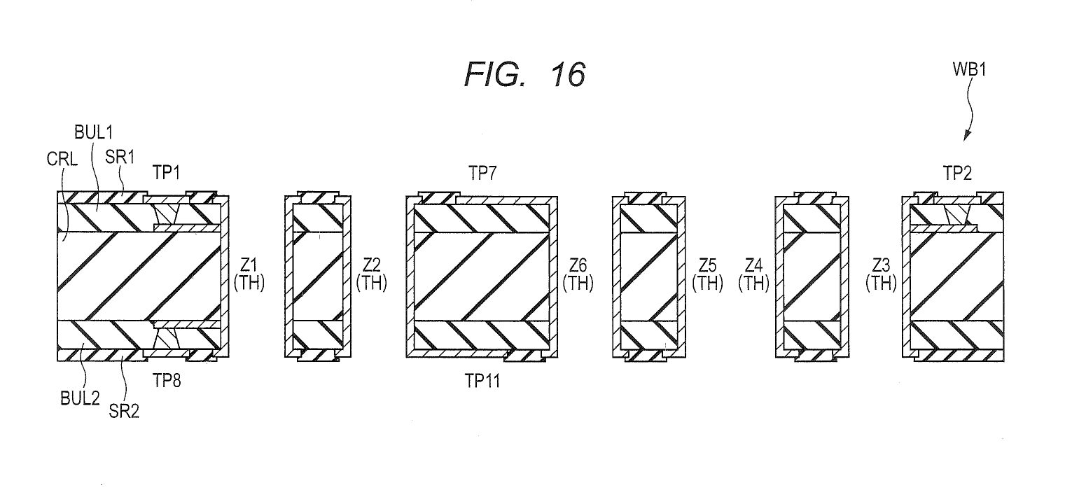

Next, FIG. 16 is a sectional diagram cut along line A-A of FIG. 14. As shown in FIG. 16, the wiring board WB1 in the present embodiment has a core layer CRL, a build-up layer BUL1 and a build-up layer BUL2 which interpose the core layer CRL therebetween, a solder resist SR1 which comes into contact with the build-up layer BUL1, and a solder resist SR2 which comes into contact with the build-up layer BUL2. Further, as shown in FIG. 16, the through holes TH passing through the core layer CRL, the build-up layer BUL1, and the build-up layer BUL2 are formed in the wiring board WB1. For example, the six through holes TH respectively configure the external power supply terminal Z1, the GND terminal Z2, the first external sensor input terminal Z3, the first external sensor GND terminal Z4, the second external sensor GND terminal Z5, and the second external sensor input terminal Z6. In FIG. 16, for example, the external power supply terminal Z1 is electrically coupled to the test terminal TP1 exposed from the solder resist SR1 through a wiring and a via formed in the build-up layer BUL1 and electrically coupled to the test terminal TP8 exposed from the solder resist SR2 through a wiring and a via formed in the build-up layer BUL2. Also, the GND terminal Z2 is electrically coupled to the test terminal TP11, and the second external sensor input terminal Z6 is electrically coupled to the test terminal TP7. Further, the first external sensor input terminal Z3 is electrically coupled to the test terminal TP2 exposed from the solder resist SR1 through a wiring and a via formed in the build-up layer BUL1.

<Coupling Relationship Between Terminals Used in Test Process>

While the test terminals are provided over both surfaces of the wiring board WB1 as described above, for example, the semiconductor device SA1 and the connector CNT1 are mounted over the wiring board WB1, and the external terminals TE1 are provided at the wiring board WB1 as shown in FIG. 14. At this time, the test process in the present embodiment is carried out using not only the test terminals provided over both surfaces of the wiring board WB1, but also the semiconductor device (microcomputer) SA1 and the connector CNT1 mounted over the wiring board WB1 and the external terminals TE1 provided at the wiring board WB1.

Therefore, a description will be made below about one example of a coupling relationship among a plurality of test terminals used in the test process in the present embodiment, microcomputer terminals for the semiconductor device SA1, connector terminals for the connector CNT1, and external terminals TE1.

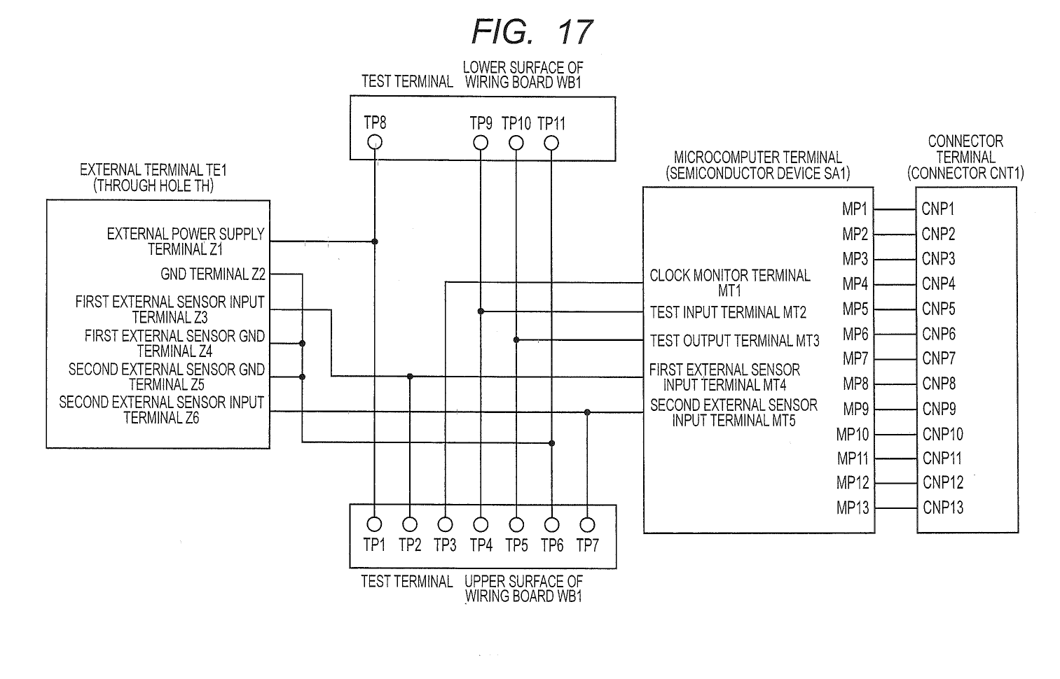

FIG. 17 is a coupling diagram showing one example of the coupling relationship between the terminals used in the test process in the present embodiment. In FIG. 17, the external terminals TE1 passing through the wiring board WB1 include an external power supply terminal Z1, a GND terminal Z2, a first external sensor input terminal Z3, a first external sensor GND terminal Z4, a second external sensor GND terminal Z5, and a second external sensor input terminal Z6. Also, while the test terminals provided over the upper surface of the wiring board WB1 include test terminals TP1 to TP7, the test terminals provided over the lower surface of the wiring board WB1 include test terminals TP8 to TP11. Further, the semiconductor device SA1 mounted over the upper surface of the wiring board WB1 has a plurality of microcomputer terminals. The microcomputer terminals include a clock monitor terminal TM1, a test input terminal MT2, a test output terminal MT3, a first external sensor input terminal MT4, a second external sensor input terminal MT5, and microcomputer terminals MP1 to MP13. Further, the connector CNT1 mounted over the upper surface of the wiring board WB1 has a plurality of connector terminals. The connector terminals CNT1 include connector terminals CNP1 to CNP13.

As shown in FIG. 17, the external power supply terminal Z1 is coupled to the test terminal TP1 and the test terminal TP8. The GND terminal Z2 is coupled to the first external sensor GND terminal Z4 and the second external sensor GND terminal Z5 and coupled to the test terminal TP6 and the test terminal TP11. Further, the first external sensor input terminal Z3 is coupled to the test terminal TP2 and coupled to the first external sensor input terminal MT4. The second external sensor input terminal Z6 is coupled to the test terminal TP7 and coupled to the second external sensor input terminal MT5.

Further, as shown in FIG. 17, the test input terminal MT2 is coupled to the test terminal TP4 and the test terminal TP9. The test output terminal MT3 is coupled to the test terminal TP5 and the test terminal TP10. Further, the microcomputer terminals MP1 to MP13 are respectively coupled to the connector terminals CNP1 to CNP13.

<Details of Unit Test Process>

Subsequently, the details of the unit test process for the wiring board WB1 will be described. First, in FIG. 17, the unit test on the wiring board WB1 in the present embodiment is carried out by pressing a test probe against each of the connector terminals CNP1 to CNP13 of the connector CNT1 coupled to the wiring board WB2 (not shown). Specifically, the connector terminals CNP1 to CNP13 are coupled to the microcomputer terminals MP1 to MP13 of the semiconductor device SA1 which functions as the microcomputer (micon). The coupling test with the microcomputer terminals MP1 to MP13 is performed by pressing the test probe against each of the connector terminals CNP1 to CNP13. Here, in FIG. 17, the external power supply terminal Z1 and the GND terminal Z2 drawn as the external terminals TE1 are used for the supply of a power supply potential and a GND potential during the unit test on the wiring board WB1. Further, the first external sensor input terminal Z3 and the second external sensor input terminal Z6 are drawn with the first external sensor input terminal MT4 and the second external sensor input terminal MT5 being the microcomputer terminals of the semiconductor device SA1 as the external terminals TE1, and are required to be tested in order to perform coupling confirmation of the microcomputer terminals. Since, however, the external terminals TE1 are made up of the through holes TH as shown in FIG. 14, and the area of a land (land LNDA in FIG. 14) around each through hole TH becomes very small, it becomes difficult to press the test probe against this land. From this point of view, in the present embodiment, the unit test is to be carried out by providing the test terminals TP1 to TP7 coupled to the external terminals TE1 as shown in FIG. 17 and pressing the test probe against each of the test terminals TP1 to TP7. Further, in the unit test on the wiring board WB1, test signals are transmitted to the test input terminal MT2 and the test output terminal MT3 of the semiconductor device (micon) SA1 to control the semiconductor device SA1, whereby the unit test on the wiring board WB1 is performed. Since there is adopted a configuration for monitoring a clock signal of the semiconductor device SA1 to shorten a test time in the unit test on the wiring board WB1 in the present embodiment, the clock monitor terminal MT1 of the semiconductor device SA1 is coupled to the test terminal (test terminal TP3) and the test probe is pressed against this test terminal.

Incidentally, as the microcomputer terminals for the semiconductor device SA1, microcomputer terminals exist even besides the microcomputer terminals MP1 to MP13 coupled to the connector terminals CNP1 to CNP13, the first external sensor input terminal MT4 and the second external sensor input terminal MT5 coupled to the external terminals TE1, the test input terminal MT2, the test output terminal MT3, and the clock monitor terminal MT1. Also, the microcomputer terminals are microcomputer terminals coupled to the op amplifier OPAMP, the regulator RGL, the crystal oscillator Xtal1, and the sensor module SM mounted over the wiring board WB1 as shown in FIGS. 14 and 15. Further, test signals are sent to the test input terminal MT2 and the test output terminal MT3 to thereby confirm the function operations of the op amplifier OPAMP, the regulator RGL, the crystal oscillator Xtal1, and the sensor module SM through the semiconductor device SA1, so that coupling confirmation between these electronic components and the semiconductor device SA1 can be done.

The unit test on the wiring board WB1 described as above is carried out by pressing the test probe against each of the connector terminals CNP1 to CNP13 and the test terminals TP1 to TP7 provided over the upper surface of the wiring board WB1 while pressing and fixing the lower surface of the wiring board WB1 by a testing jig. From this point, as shown in FIG. 14, the test terminals TP1 to TP7 used in the unit test in the present embodiment are disposed over the same surface (upper surface of wiring board WB1) as the connector CNT1 having the connector terminals CNP1 to CNP13.

<Details of Coupling Test Process>

A description will next be made about the details of a coupling test process after the wiring board WB1 and the wiring board WB2 are laminated and coupled to form the module unit MJU1. In the present embodiment, the coupling test on the module unit MJU1 is performed after the unit test on the wiring board WB1 and the unit test on the wiring board WB2 are carried out. Therefore, since the wiring board WB1 and the wiring board WB2 which configure the module unit MJU1 assembled in the present embodiment have been confirmed to be non-defective products, coupling confirmation at the connector CNT1 is performed in the coupling test on the module unit MJU1. When performing the coupling test, it is carried out using the test terminal TP8 coupled to the external power supply terminal Z1, the test terminal TP11 coupled to the GND terminal Z2, the test terminal TP9 coupled to the test input terminal MT2, and the test terminal TP10 coupled to the test output terminal MT3 as shown in FIG. 17 to control the semiconductor device (microcomputer) SA1. Thus, the coupling test on the module unit MJU1 is carried out using the wiring board WB1 formed with the external power supply terminal Z1. Since it is not possible to press the test probe against the upper surface of the wiring board WB1 after the wiring board WB1 and the wiring board WB2 are laminated and coupled to form the module unit MJU1, the coupling test on the module unit MJU1 is carried out while pressing the test probe against the lower surface of the wiring board WB1. Accordingly, the test terminals TP8 to TP11 used in the coupling test on the module unit MJU1 are provided over the lower surface of the wiring board WB1 as shown in FIG. 15. From the above, in the wiring board WB1 in the present embodiment, the unit test is performed while pressing the test probe against the upper surface of the wiring board WB1, and the coupling test is performed while pressing the test probe against the lower surface of the wiring board WB1. Therefore, in the present embodiment, the test terminals TP8 to TP11 used in the coupling test are provided over the upper surface of the wiring board WB1, while the test terminals TP1 to TP7 used in the unit test are provided over the upper surface of the wiring board WB1. In other words, the wiring board WB1 in the present embodiment is provided with the test terminals at both of the upper and lower surfaces.

<Features of Embodiment>

The wiring board WB1 in the present embodiment is mounted with the electronic components and provided with the external terminals TE1 and the test terminals TP1 to TP11. Thus, upon promoting miniaturization of the electronic apparatus including the wiring board WB1, it is important to devise not only the arrangement configuration of the electronic components but also the arrangement configuration and shapes of the external terminals TE1 and test terminals TP1 to TP11. Thus, in the present embodiment, particularly, the arrangement configuration and shapes of the external terminals TE1 and test terminals TP1 to TP11 provided over the wiring board WB1 are devised to realize miniaturization of the wiring board WB1. A description will be made below about feature points in the present embodiment which has been given this devisal.

The first feature point in the present embodiment resides in that the test terminals TP1 to TP6 provided over the upper surface of the wiring board WB1 are collectively disposed as shown in FIG. 14, for example. Thus, the size of the test terminal forming area (first test terminal forming area) with the test terminals TP1 to TP6 used in the unit test formed therein can be reduced. As a result, according to the present embodiment, since the area occupied by the test terminal forming area relative to the entire upper surface of the wiring board WB1 can be reduced as much as possible by collectively arranging the test terminals TP1 to TP6, the size of the wiring board WB1 can be reduced. Thus, it is possible to achieve miniaturization of the electronic apparatus according to the present embodiment.

Similarly, in the present embodiment, the test terminals TP8 to TP10 provided over the lower surface of the wiring board WB1 are also collectively arranged as shown in FIG. 15, for example. Thus, the size of the test terminal forming area (second test terminal forming area) with the test terminals TP8 to TP10 used in the coupling test being formed therein can be reduced. As a result, according to the present embodiment, the area occupied by the test terminal forming area relative to the entire lower surface of the wiring board WB1 can be reduced as much as possible by collectively arranging the test terminals TP8 to TP10, thereby making it possible to reduce the size of the wiring board WB1. Thus, it is possible to achieve miniaturization of the electronic apparatus according to the present embodiment.

In the present embodiment in particular, since the test terminal forming area is formed over the upper surface of the wiring board WB1, close to the corner of the wiring board WB1 so as to include part of the side SD1 and part of the side SD2 in the wiring board WB1 as shown in FIG. 14, the size of the wiring board WB1 can be miniaturized while ensuring the area of the part mounting area with the electronic components mounted therein. Likewise, since the test terminal forming area is formed over the lower surface of the wiring board WB1, close to the outer edge portion of the wiring board WB1 so as to include part of the side SD1 of the wiring board WB1 as shown FIG. 15, the size of the wiring board WB1 can be made small while ensuring the area of the part mounting area with the electronic components mounted therein.

Further, in the present embodiment, as shown in FIG. 14, the buffer area BUR1 having the prescribed space is provided between the test terminal forming area and the part mounting area in plan view. Such a buffer area BUR1 is provided to avoid interference of the test probe with the electronic components mounted over the upper surface of the wiring board WB1 upon pressing the test probe against each of the test terminals TP1 to TP6 formed in the test terminal forming area. That is, although the buffer area BUF1 is required in terms of avoiding the interference of the test probe with the electronic components, the size of the wiring board WB1 becomes large as the area occupied by the buffer area BUF1 increases. In this regard, in the present embodiment, the test terminal forming area in which the test terminals TP1 to TP6 provided over the upper surface of the wiring board WB1 are collectively arranged, is formed close to the corner of the wiring board WB1 as shown in FIG. 14, for example. From this point, according to the present embodiment, the buffer area BUR1 provided between the test terminal forming area and the part mounting area can be set to a minimum required area. Thus, according to the present embodiment, an increase in the size of the wiring board WB1 due to the provision of the buffer area BUF1 can be suppressed to the necessary minimum limit while providing the buffer area BUF1 for avoiding the interference of the test probe with the electronic components. Thus, it is possible to achieve miniaturization of the wiring board WB1.

Similarly, in the present embodiment, as shown in FIG. 15, for example, the test terminal forming area in which the test terminals TP8 to TP10 provided over the lower surface of the wiring board WB1 are collectively arranged is formed close to the outer edge portion of the wiring board WB1. From this point, according to the present embodiment, the buffer area BUR2 provided between the test terminal forming area and the part mounting area can be set to the required minimum area. Thus, according to the present embodiment, an increase in the size of the wiring board WB1 due to the provision of the buffer area BUF2 can be suppressed to the necessary minimum limit while providing the buffer area BUF2 for avoiding the interference of the test probe with the electronic components, thus making it possible to achieve miniaturization of the wiring board WB1.

Subsequently, the second feature point in the present embodiment resides in that as shown in FIG. 14, for example, the test terminal TP7 is provided in the area different from the test terminal forming area in which the test terminals TP1 to TP6 are collectively arranged, at the upper surface of the wiring board WB1. Specifically, the through holes TH which function as the external terminals TE1 are formed in the upper surface of the wiring board WB1 along the side SD4. The lands respectively including the through holes TH in plan view are respectively formed at the through holes TH. At this time, in FIG. 14, for example, the land LNDB corresponding to the second external sensor input terminal Z6 of the through holes TH is larger in area than the land LNDA including each of other through holes TH. The land LNDB functions as one test terminal TP7 different from the test terminals TP1 to TP6 formed in the test terminal forming area. That is, although the test terminals TP1 to TP6 are collectively arranged in the test terminal forming area as in the above-described first feature point in the present embodiment, there is a case where it becomes difficult to form the test terminal TP7 used in the unit test in the test terminal forming area as a result of reducing the area occupied by the test terminal forming area in terms of miniaturization of the wiring board WB1. In this case, as in the second feature point in the present embodiment, the land LNDB of the partial through hole TH is expanded and thereby the expanded land LNDB is allowed to function as the test terminal TP7. Thus, according to the present embodiment, there has basically been given a device that the area in which the land LNDB of the partial through hole TH is expanded is used as the test terminal TP7 failed to enter into the test terminal forming area small in the occupied area while realizing the first feature point that the test terminals TP1 to TP6 are collectively arranged in the test terminal forming area small in the occupied area (second feature point). As a result, according to the present embodiment, the test terminals TP1 to TP7 necessary for the unit test on the wiring board WB1 can all be arranged over the upper surface of the wiring board WB1 while complying with a demand for miniaturization of the wiring board WB1 as much as possible. That is, in the present embodiment, the miniaturization of the target wiring board WB1 can be realized by combining the first feature point and the second feature point.

Likewise, as shown in FIG. 15, for example, the land LNDD corresponding to the GND terminal Z2 of the through holes TH is larger in area than the land LNDC including each of the other through holes TH even at the lower surface of the wiring board WB1. Further, the land LNDD is configured so as to function as one test terminal TP11 different from the test terminals TP8 to TP19 formed in the test terminal forming area. Thus, according to the present embodiment, the test terminals TP8 to TP11 necessary for the coupling test on the module unit MJU1 can all be arranged over the lower surface of the wiring board WB1 while complying with a demand for miniaturization of the wiring board WB1 as much as possible even at the lower surface of the wiring board WB1.

According to the present embodiment in particular, as shown in FIGS. 14 and 15 and 16, the wide land LNDB which functions as the test terminal TP7, and the wide land LNDD which functions as the test terminal TP11 are disposed so as to overlap with each other in plan view. This means that the wide land LNDB at the upper surface of the wiring board WB1 and the wide land LNDD at the lower surface of the wiring board WB1 can efficiently be arranged. Consequently, further, the miniaturization of the wiring board WB1 can be realized.

Next, the third feature point in the present embodiment resides in that as shown in FIGS. 14 and 15, for example, the through holes TH larger in opening area than other through holes TH are included in the through holes TH. Specifically, for example, there is given a device that since the occupied areas for disposing the six through holes TH become large if the six through holes are respectively arranged at equal intervals, although the six through holes TH are formed in the wiring board WB1, the occupied areas are made smaller than in the case of the configuration of disposing the six through holes at equal intervals in the present embodiment. That is, the third feature point in the present embodiment which is this devised point is that for example, the first external sensor GND terminal Z4 and the second external sensor GND terminal Z5 are coupled to each other. Thus, according to the present embodiment, the occupied areas for disposing the six through holes TH can respectively be reduced by unnecessity of a space between the first external sensor GND terminal Z4 and the second external sensor GND terminal Z5.

As shown in FIG. 11, for example, in the present embodiment, the thermistor TH1 and the thermistor TH2 are provided. The first external sensor corresponds to the thermistor TH1, and the second external sensor corresponds to the thermistor TH2. Further, as shown in FIG. 11, the thermistor TH1 is comprised of a sensor part (resistance part) and two wirings WL3. At this time, while the one wiring WL3 is inserted into the first external sensor input terminal Z3, the other wiring WL3 is inserted into the first external sensor GND terminal Z4. Likewise, the thermistor TH2 is comprised of a sensor part (resistance part) and two wirings WL4. While the one wiring WL4 is inserted into the second external sensor input terminal Z6, the other wiring WL4 is inserted into the second external sensor GND terminal Z5.

Here, the first external sensor GND terminal Z4 and the second external sensor GND terminal Z5 are both supplied with the GND potential. In other words, the first external sensor GND terminal Z4 and the second external sensor GND terminal Z5 are supplied with the same potential. Focusing on this point, in the present embodiment, the first external sensor GND terminal Z4 and the second external sensor GND terminal Z5 are devised so as to be placed in adjacent positions, and the first external sensor GND terminal Z4 and the second external sensor GND terminal Z5 are coupled to each other. As a result, according to the present embodiment, the occupied areas for disposing the six through holes TH can respectively be reduced by unnecessity of the space between the first external sensor GND terminal Z4 and the second external sensor GND terminal Z5.

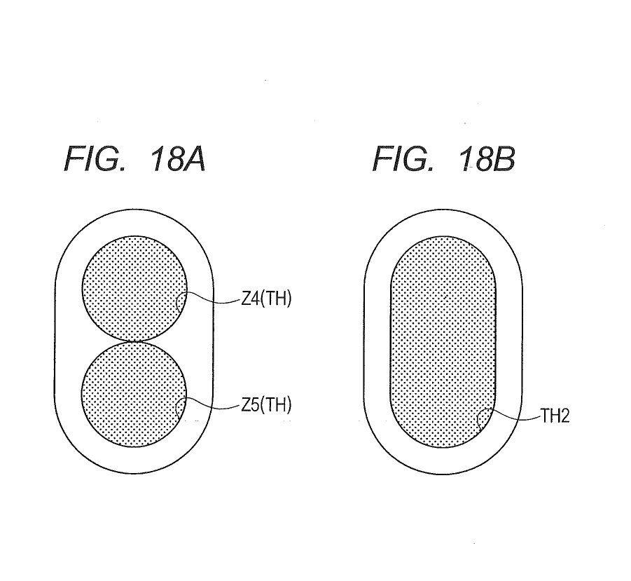

At this time, there can also be adopted such a configuration that a through hole TH corresponding to the first external sensor GND terminal Z4, and a through hole TH corresponding to the second external sensor GND terminal Z5 are coupled as shown in FIG. 18A, for example. Without being limited to this, however, as shown in FIG. 18B, for example, a long hole TH2 can also be formed in which the through hole TH corresponding to the first external sensor GND terminal Z4 and the through hole TH corresponding to the second external sensor GND terminal Z5 are integrated.

As described above, according to the third feature point indicative of the device related to the arrangement configuration of the six through holes TH, the miniaturization of the wiring board WB1 can be promoted, Thus, according to the present embodiment, the miniaturization of the wiring board WB1 can be promoted at the upper surface of the wiring board WB1 by a synergistic effect between the first and second feature points each related to the arrangement positions of the test terminals TP1 to TP7, and the third feature point related to the arrangement configuration of the through holes TH. Likewise, the miniaturization of the wiring board WB1 can be promoted at the lower surface of the wiring board WB1 by a synergistic effect between the first and second feature points each related to the arrangement positions of the test terminals TP8 to TP11, and the third feature point related to the arrangement configuration of the through holes TH.

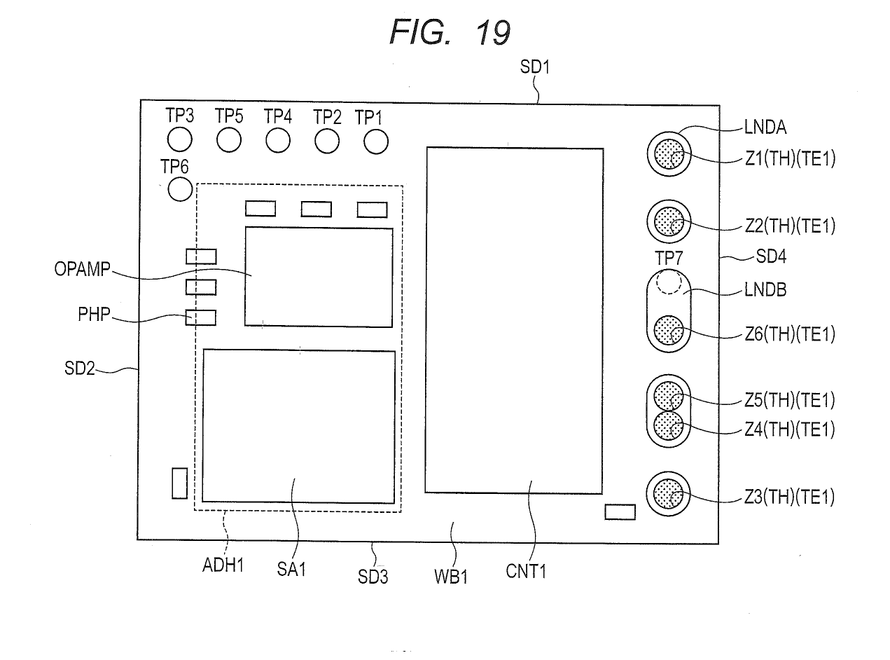

At last, a description will be made about the four feature point in the present embodiment. FIG. 19 is a plan diagram showing the upper surface of the wiring board WB1 in the present embodiment. In FIG. 19, a broken line indicates an area in which the adhesive ADH1 is formed. That is, in the module unit MJU1 in the present embodiment, as shown in FIG. 10, for example, the wiring board WB1 and the wiring board WB2 are coupled by the connector CNT1 and coupled even by the adhesive ADH1. Thus, according to the module unit MJU1 in the present embodiment, the strength of coupling between the wiring board WB1 and the wiring board WB2 can be improved.

In the present embodiment, however, as shown in FIG. 19, the adhesive ADH1 is formed so as not to contact the test terminals TP1 to TP6. This point is the fourth feature point in the present embodiment. According to the fourth feature point, there can be obtained an advantage that for example, even when the wiring board WB1 and the wiring board WB2 are separated from each other upon a failure analysis in the module unit MJU1 and to exchange the wiring board WB2 to one having another communication function, the test terminals TP1 to TP6 become easy to use because no adhesive ADH1 exists in the surfaces of the test terminals TP1 to TP6. Specifically, when the failure analysis is performed, it is carried out while pressing the test probe against each of the test terminals TP1 to TP6 of the separated wiring board WB1. It is, however, concerned that when the adhesive ADH1 is being applied to the surfaces of the test terminals TP1 to TP6, a failure in conduction between each of the test terminals TP1 to TP6 and the test probe will be caused. In terms of this point, according to the fourth feature point in the present embodiment, it becomes easy to ensure conductive contact between the test terminals TP1 to TP6 and the test probe because no adhesive ADH1 exists in the surfaces of the test terminals TP1 to TP6, thus making it possible to obtain an advantage that the failure analysis can be carried out smoothly.

Although the invention made above by the present inventors has been described specifically on the basis of the preferred embodiments, the present invention is not limited to the embodiments referred to above. It is needless to say that various changes can be made thereto within the scope not departing from the gist thereof.

The above embodiment includes the following mode.

(Appendix 1)

An electronic apparatus functioning as a component of a wireless communication system, which includes:

a first wiring board, and

a second wiring board electrically coupled to the first wiring board via a connector,

in which the first wiring board and the second wiring board are laminated and arranged in an opposed state of an upper surface of the wiring board and a lower surface of the second wiring board to configure a module unit,

in which a plurality of first test terminals are collectively provided in a first test terminal forming area of the upper surface of the first wiring board, and

in which a plurality of second test terminals are collectively provided in a second test terminal forming area of the lower surface of the first wiring board.

What is claimed is:

1. An electronic apparatus functioning as a component of a wireless communication system, comprising:
a first wiring board; and
a second wiring board electrically coupled to the first wiring board via a connector,
the first wiring board and the second wiring board being laminated and arranged in an opposed state of an upper surface of the wiring board and a lower surface of the second wiring board to configure a module unit,
the upper surface of the first wiring board having a first test terminal forming area collectively provided with a plurality of first test terminals.

2. The electronic apparatus according to claim 1, wherein the first test terminals are unit test terminals relative to the single first wiring board prior to the configuration of the module unit.

3. The electronic apparatus according to claim 1, wherein the upper surface of the first wiring board has a first part mounting area with electronic components mounted thereover, and
wherein a first buffer area having a prescribed space is provided between the first test terminal forming area and the first part mounting area in plan view.

4. The electronic apparatus according to claim 1, wherein the first wiring board has a first side and a second side which intersects with the first side, and
wherein a visible outline of the first test terminal forming area includes a part of the first side and a part of the second side.

5. The electronic apparatus according to claim 1, wherein the upper surface of the first wiring board has a through hole forming area in which a plurality of through holes are formed, and
wherein the first test terminals and the through holes are respectively electrically coupled.

6. The electronic apparatus according to claim 5, wherein the first test terminals are unit test terminals relative to the single first wiring board prior to the configuration of the module unit,
wherein a plurality of lands respectively electrically coupled to the through holes and including the through holes in plan view are formed over the upper surface of the first wiring board,
wherein a first land corresponding to a first through hole of the through holes is the largest in area within the lands, and
wherein the first land functions as one the unit test terminal different from the first test terminals formed in the first test terminal forming area.

7. The electronic apparatus according to claim 5, wherein the through holes include therein a second through hole larger in opening area than other through holes.

8. The electronic apparatus according to claim 1, wherein a plurality of second test terminals are collectively provided in a second test terminal forming area of a lower surface of the first wiring board.

9. The electronic apparatus according to claim 8, wherein the second test terminals are coupling test terminals with the first wiring board and the second wiring board in the module unit in which the first wiring board and the second wiring board are laminated and arranged.

10. The electronic apparatus according to claim 8, wherein the lower surface of the first wiring board has a second part mounting area with electronic components mounted thereover, and
wherein a second buffer area having a prescribed space is provided between the second test terminal forming area and the second part mounting area in plan view.

11. The electronic apparatus according to claim 8, wherein the first wiring board has a first side, and
wherein a visible outline of the second test terminal forming area includes a part of the first side.

12. The electronic apparatus according to claim 8, wherein the lower surface of the first wiring board has a through hole forming area in which a plurality of through holes are formed, and
wherein the second test terminals and the through holes are respectively electrically coupled.

13. The electronic apparatus according to claim 12, wherein a plurality of lands respectively electrically coupled to the through holes and including the through holes in plan view are formed over the lower surface of the first wiring board,
wherein a second land corresponding to a second through hole of the through holes is the largest in area within the lands, and
wherein the second land functions as a second test terminal different from the second test terminals formed in the second test terminal forming area.

14. The electronic apparatus according to claim 1, wherein the first wiring board and the second wiring board are coupled to each other even by an adhesive, and
wherein the adhesive is in non-contact with the first test terminals.

15. A method for manufacturing an electronic apparatus functioning as a component of a wireless communication system,
the electronic apparatus being equipped with a first wiring board, and a second wiring board electrically coupled to the first wiring board via a connector,
the first wiring board and the second wiring board being laminated and arranged in an opposed state of an upper surface of the first wiring board and a lower surface of the second wiring board to configure a module unit,
the upper surface of the first wiring board including therein a first test terminal forming area in which a plurality of first test terminals being collectively provided, and
the lower surface of the first wiring board including therein a second test terminal forming area in which a plurality of second test terminals being collectively provided, the method comprising the steps of:
(a) mounting electronic components over the upper surface of the first wiring board;
(b) mounting electronic components over the lower surface of the first wiring board;
(c) after execution of the (a) step and the (b) step, performing a unit test on the first wiring board by using the first test terminals;
(d) after the (c) step, coupling the first wiring board and the second wiring board having passed the unit test to each other by the connector to thereby form the module unit; and
(e) after the (d) step, performing a coupling test on the module unit by using the second terminals.
